(19) United States
(12) Patent Application Publication
(10) Pub. No.: US 2026/0114059 A1
(43) Pub. Date: Apr. 23, 2026

(54) SOLID-STATE IMAGING DEVICE

(71) Applicant: SONY SEMICONDUCTOR SOLUTIONS CORPORATION, KANAGAWA (JP)

(72) Inventors: Daichi TANAKA, KANAGAWA (JP); Chihiro TOMITA, KANAGAWA (JP)

(21) Appl. No.: 19/117,057

(22) PCT Filed: Aug. 17, 2023
(86) PCT No.: PCT/JP2023/029670

§ 371 Date: Mar. 30, 2025

(30) Foreign Application Priority Data
Oct. 4, 2022 (JP) 2022-160068

(51) Int. Cl. H10F 39/00

(52) U.S. Cl. CPC H10F 39/80373; H10F 39/807

(57) ABSTRACT

A solid-state imaging device includes: a first pixel that is provided on a side of a first surface of a base, and includes a first photoelectric conversion element that converts light into electric charge, the side of the first surface being a light incident side; a first transistor that is provided on a side of a second surface opposite to the first surface of the base at a position corresponding to the first pixel, and includes a first gate electrode and a pair of main electrodes, one of the pair of main electrodes being electrically coupled to the first photoelectric conversion element; a floating diffusion that is provided on the side of the second surface of the base, and is electrically coupled to another main electrode of the first transistor; and a low-dielectric constant region that is provided between the floating diffusion and the first gate electrode opposed to the floating diffusion, and has a lower dielectric constant than a dielectric constant of a non-opposed region.

### TECHNICAL FIELD

The present disclosure relates to a solid-state imaging device.

### Background Art

PTL 1 discloses a solid-state imaging device. The solid-state imaging device includes a photoelectric converter for each of a plurality of pixels regularly arranged. The photoelectric converter generates electric charge as a signal from incident light. The signal is transferred to a floating diffusion through a transfer transistor provided for each pixel. The floating diffusion transfers the signal to a pixel circuit, and the pixel circuit processes the signal. The floating diffusion is shared by a plurality of pixels arranged adjacent to each other.

### CITATION LIST

### Patent Literature

PTL 1: International Publication No. WO2020/262643

### SUMMARY OF THE INVENTION

Incidentally, in a manufacturing process of a solid-state imaging device, misalignment of a floating diffusion occurs with respect to a gate electrode of a transfer transistor for each of a plurality of pixels, specifically, a contact section that supplies a control signal to the gate electrode. This misalignment results in variations in parasitic capacitance generated by a shared contact section of each pixel and the floating diffusion. Accordingly, in the solid-state imaging device, it is desirable to suppress signal variations and signal delay due to the parasitic capacitance.

A solid-state imaging device according to a first aspect of the present disclosure includes: a first pixel that is provided on a side of a first surface of a base, and includes a first photoelectric conversion element that converts light into electric charge, the side of the first surface being a light incident side; a first transistor that is provided on a side of a second surface opposite to the first surface of the base at a position corresponding to the first pixel, and includes a first gate electrode and a pair of main electrodes, one of the pair of main electrodes being electrically coupled to the first photoelectric conversion element; a floating diffusion that is provided on the side of the second surface of the base, and is electrically coupled to another main electrode of the first transistor; and a low-dielectric constant region that is provided between the floating diffusion and the first gate electrode opposed to the floating diffusion, and has a lower dielectric constant than a dielectric constant of a non-opposed region.

A solid-state imaging device according to a second aspect of the present disclosure further includes a second pixel, a second transistor, and the low-dielectric constant region, in the solid-state imaging device according to the first aspect. The second pixel is provided adjacent to the first pixel on the side of the first surface of the base, and includes a second photoelectric conversion element that converts light into electric charge. The second transistor is provided on the side of the second surface of the base at a position corresponding to the second pixel, and includes a second gate electrode and a pair of main electrodes, one of the pair of main electrodes being electrically coupled to the second photoelectric conversion element, and another main electrode being electrically coupled to the floating diffusion. The low-dielectric constant region is provided between the floating diffusion and the second gate electrode opposed to the floating diffusion.

In a solid-state imaging device according to a third aspect of the present disclosure, the low-dielectric constant region includes a gap in the solid-state imaging device according to the first aspect or the second aspect.

In a solid-state imaging device according to a fourth aspect of the present disclosure, the low-dielectric constant region is formed by a low-dielectric constant material in the solid-state imaging device according to the first aspect or the second aspect.

### BRIEF DESCRIPTION OF THE DRAWINGS

FIG. 1 is a circuit diagram illustrating a pixel and a pixel circuit of a solid-state imaging device according to a first embodiment of the present disclosure.

FIG. 2 is a longitudinal cross-sectional configuration diagram (a cross-sectional view taken along a cutting line A-A illustrated in FIG. 3) of the pixel illustrated in FIG. 1.

FIG. 3 is a planar configuration diagram of the pixel illustrated in FIG. 1.

FIG. 4 is a first step cross-sectional view describing, step-by-step, a manufacturing method of the solid-state imaging device according to the first embodiment.

FIG. 5 is a second step cross-sectional view.

FIG. 6 is a third step cross-sectional view.

FIG. 7 is a fourth step cross-sectional view.

FIG. 8 is a fifth step cross-sectional view.

FIG. 9 is a sixth step cross-sectional view.

FIG. 10 is a seventh step cross-sectional view.

FIG. 11 is an eighth step cross-sectional view.

FIG. 12 is a ninth step cross-sectional view.

FIG. 13 is a tenth step cross-sectional view.

FIG. 14 is an eleventh step cross-sectional view.

FIG. 15 is a twelfth step cross-sectional view.

FIG. 16 is a thirteenth step cross-sectional view.

FIG. 17 is a fourteenth step cross-sectional view.

FIG. 18 is a fifteenth step cross-sectional view.

FIG. 19 is a sixteenth step cross-sectional view.

FIG. 20 is a seventeenth step cross-sectional view.

FIG. 21 is an eighteenth step cross-sectional view.

FIG. 22 is a nineteenth step cross-sectional view.

FIG. 23 is a twentieth step cross-sectional view.

FIG. 24 is a twenty-first step cross-sectional view.

FIG. 25 is a twenty-second step cross-sectional view.

FIG. 26 is a longitudinal cross-sectional configuration diagram (a cross-sectional view taken along a cutting line B-B illustrated in FIG. 27), corresponding to FIG. 2, of a pixel of a solid-state imaging device according to a second embodiment of the present disclosure.

FIG. 27 is a planar configuration diagram, corresponding to FIG. 3, of the pixel illustrated in FIG. 26.

FIG. 28 is a longitudinal cross-sectional configuration diagram (a cross-sectional view taken along a cutting line C-C illustrated in FIG. 29), corresponding to FIG. 2, of a pixel of a solid-state imaging device according to a third embodiment of the present disclosure.

FIG. 29 is a planar configuration diagram, corresponding to FIG. 3, of the pixel illustrated in FIG. 28.

FIG. 30 is a longitudinal cross-sectional configuration diagram (a cross-sectional view taken along a cutting line D-D illustrated in FIG. 31), corresponding to FIG. 2, of a pixel of a solid-state imaging device according to a fourth embodiment of the present disclosure.

FIG. 31 is a planar configuration diagram, corresponding to FIG. 3, of the pixel illustrated in FIG. 30.

FIG. 32 is a longitudinal cross-sectional configuration diagram (a cross-sectional view taken along a cutting line E-E illustrated in FIG. 33), corresponding to FIG. 2, of a pixel of a solid-state imaging device according to a fifth embodiment of the present disclosure.

FIG. 33 is a planar configuration diagram, corresponding to FIG. 3, of the pixel illustrated in FIG. 32.

FIG. 34 is a longitudinal cross-sectional configuration diagram (a cross-sectional view taken along a cutting line F-F illustrated in FIG. 35), corresponding to FIG. 2, of a pixel of a solid-state imaging device according to a sixth embodiment of the present disclosure.

FIG. 35 is a planar configuration diagram, corresponding to FIG. 3, of the pixel illustrated in FIG. 34.

FIG. 36 is a first step cross-sectional view describing, step-by-step, a manufacturing method of the solid-state imaging device according to the sixth embodiment.

FIG. 37 is a second step cross-sectional view.

FIG. 38 is a third step cross-sectional view.

FIG. 39 is a fourth step cross-sectional view.

FIG. 40 is a fifth step cross-sectional view.

FIG. 41 is a sixth step cross-sectional view.

FIG. 42 is a seventh step cross-sectional view.

FIG. 43 is an eighth step cross-sectional view.

FIG. 44 is a ninth step cross-sectional view.

FIG. 45 is a tenth step cross-sectional view.

FIG. 46 is an eleventh step cross-sectional view.

FIG. 47 is a twelfth step cross-sectional view.

FIG. 48 is a thirteenth step cross-sectional view.

FIG. 49 is a fourteenth step cross-sectional view.

FIG. 50 is a fifteenth step cross-sectional view.

FIG. 51 is a sixteenth step cross-sectional view.

FIG. 52 is a seventeenth step cross-sectional view.

FIG. 53 is an eighteenth step cross-sectional view.

FIG. 54 is a nineteenth step cross-sectional view.

FIG. 55 is a twentieth step cross-sectional view.

FIG. 56 is a twenty-first step cross-sectional view.

FIG. 57 is a twenty-second step cross-sectional view.

FIG. 58 is a twenty-third step cross-sectional view.

FIG. 59 is a twenty-fourth step cross-sectional view.

FIG. 60 is a longitudinal cross-sectional configuration diagram (a cross-sectional view taken along a cutting line G-G illustrated in FIG. 61), corresponding to FIG. 2, of a pixel of a solid-state imaging device according to a seventh embodiment of the present disclosure.

FIG. 61 is a planar configuration diagram, corresponding to FIG. 3, of the pixel illustrated in FIG. 60.

FIG. 62 is a first step cross-sectional view describing, step-by-step, a manufacturing method of the solid-state imaging device according to the eighth embodiment.

FIG. 63 is a second step cross-sectional view.

FIG. 64 is a third step cross-sectional view.

FIG. 65 is a fourth step cross-sectional view.

FIG. 66 is a first step cross-sectional view describing, step-by-step, a manufacturing method of a solid-state imaging device according to a ninth embodiment.

FIG. 67 is a second step cross-sectional view.

FIG. 68 is a planar configuration diagram, corresponding to FIG. 3, of a pixel of a solid-state imaging device according to a tenth embodiment of the present disclosure.

FIG. 69 is a longitudinal cross-sectional configuration diagram (a cross-sectional view taken along a cutting line H-H illustrated in FIG. 70), corresponding to FIG. 2, of a pixel of a solid-state imaging device according to an eleventh embodiment of the present disclosure.

FIG. 70 is a planar configuration diagram, corresponding to FIG. 3, of the pixel illustrated in FIG. 69.

FIG. 71 is a planar configuration diagram, corresponding to FIG. 3, of a pixel of a solid-state imaging device according to a twelfth embodiment of the present disclosure.

FIG. 72 is a block diagram depicting an example of schematic configuration of a vehicle control system that is a first application example according to an embodiment of the present disclosure.

FIG. 73 is a diagram of assistance in explaining an example of installation positions of an outside-vehicle information detecting section and an imaging section.

### MODES FOR CARRYING OUT THE INVENTION

Hereinafter, description is given in detail of embodiments of the present disclosure with reference to the drawings. It is to be noted that the description is given in the following order.

### 1. First Embodiment

A first embodiment describes an example in which the present technology is applied to a solid-state imaging device. The first embodiment describes, in detail, circuit configurations, planar configurations, and longitudinal cross-sectional configurations of a pixel and a pixel circuit of the solid-state imaging device, and a manufacturing method of the solid-state imaging device.

### 2. Second Embodiment

A second embodiment is a first example in which a separation structure between a gate electrode of a transfer transistor of the pixel and a floating diffusion is changed in the solid-state imaging device according to the first embodiment.

### 3. Third Embodiment

A third embodiment is a second example in which a structure of a pixel separation region that separates pixels from each other is changed in the solid-state imaging device according to the first embodiment.

### 4. Fourth Embodiment

A fourth embodiment is a fourth example that describes, in addition to the separation structure between the gate electrode of the transfer transistor of the pixel and the floating diffusion, a separation structure in a region other than the separation structure in the solid-state imaging device according to the first embodiment.

### 5. Fifth Embodiment

A fifth embodiment is a fifth example in which the separation structure between the gate electrode of the transfer transistor of the pixel and the floating diffusion is changed in the solid-state imaging device according to the first embodiment.

### 6. Sixth Embodiment

A sixth embodiment is a sixth example in which a structure of a shared contact section of the floating diffusion is changed in the solid-state imaging device according to the first embodiment. The manufacturing method of the solid-state imaging device is also described here.

### 7. Seventh Embodiment

A seventh embodiment is a seventh example in which a transistor that constructs a pixel circuit is provided for the pixel in the solid-state imaging device according to the first embodiment.

### 8. Eighth Embodiment

An eighth embodiment is an eighth example in which a manufacturing method of the separation structure between the gate electrode of the transfer transistor of the pixel and the floating diffusion is changed in the solid-state imaging device according to the first embodiment.

### 9. Ninth Embodiment

A ninth embodiment is a ninth example in which the manufacturing method of the separation structure between the gate electrode of the transfer transistor of the pixel and the floating diffusion is changed in the solid-state imaging device according to the first embodiment.

### 10. Tenth Embodiment

A tenth embodiment is a tenth example in which the structure of the pixel separation region that separates pixels from each other is changed in the solid-state imaging device according to the first embodiment.

### 11. Eleventh Embodiment

An eleventh embodiment is an eleventh example in which the structure of the pixel separation region that separates pixels from each other is changed in the solid-state imaging device according to the first embodiment.

### 12. Twelfth Embodiment

A twelfth embodiment is a twelfth example in which a structure of a unit pixel is changed in the solid-state imaging device according to the first embodiment.

### 13. Example of Application to Mobile Body

An example is described in which the present technology is applied to a vehicle control system that is an example of a mobile body control system.

### 14. Other Embodiments

### 1. First Embodiment

Description is given of a solid-state imaging device 1 according to the first embodiment of the present disclosure with reference to FIGS. 1 to 25.

Here, an arrow-X direction indicated as appropriate in the drawings indicates one planar direction of the solid-state imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### [Configuration of Solid-State Imaging Device 1]

### (1) Circuit Configurations of Pixel 10 and Pixel Circuit 20 of Solid-State Imaging Device 1

FIG. 1 illustrates an example of circuit configurations of a pixel 10 and a pixel circuit 20 that construct the solid-state imaging device 1.

One pixel 10 includes a series circuit of a photoelectric conversion element (a photodiode) 11 and a transistor 12. Here, four pixels 10 configure a unit pixel.

The photoelectric conversion element 11 converts light incident from outside of the solid-state imaging device 1 into electric charge (an electric signal).

The transistor 12 is used as a transfer transistor that transfers the electric charge converted in the photoelectric conversion element 11 to the pixel circuit 20. The transistor 12 is an insulated gate field effect transistor (IGFET). To describe this in detail, the transistor 12 is an IGFET of an n-channel electrically-conductive type that is a first electrically-conductive type. That is, the transistor 12 includes a gate electrode and a pair of main electrodes.

Here, the transistor 12 is a “first transistor” or a “second transistor” according to the present technology.

Of the pair of main electrodes of the transistor 12, one main electrode is electrically coupled to the photoelectric conversion element 11. Another main electrode is electrically coupled to the pixel circuit 20 with a floating diffusion (hereinafter simply referred to as an “FD”) 25 interposed therebetween. The gate electrode is coupled to an unillustrated horizontal signal line. A control signal TG is inputted from the horizontal signal line to the gate electrode. An on-operation and an off-operation of the transistor 12 are controlled by the control signal TG.

Here, the pixel circuit 20 is provided for each unit pixel. In the first embodiment, one pixel circuit 20 is provided for four pixels 10. The pixel circuit 20 performs signal processing on the electric charge converted from the light in the pixel 10.

The pixel circuit 20 includes an amplification transistor 21, a selection transistor 22, a floating diffusion conversion gain switching transistor (hereinafter simply referred to as an “FD conversion gain switching transistor”) 23, and a reset transistor 24.

A gate electrode of the amplification transistor 21 is coupled to the FD 25. The amplification transistor 21 has one main electrode coupled to a power supply voltage terminal VDD, and another main electrode coupled to one main electrode of the selection transistor 22.

A gate electrode of the selection transistor 22 is coupled to a selection signal line SEL. Another main electrode of the selection transistor 22 is coupled to a vertical signal line VSL and a current source load LC. The current source load LC is coupled to a reference volage terminal GND.

A gate electrode of the FD conversion gain switching transistor 23 is coupled to a floating diffusion control signal line FDG. The FD conversion gain switching transistor 23 has one main electrode coupled to the FD 25, and another main electrode coupled to one main electrode of the reset transistor 24.

A gate electrode of the reset transistor 24 is coupled to a reset signal line RST. Another main electrode of the reset transistor 24 is coupled to the power supply voltage terminal VDD.

In the solid-state imaging device 1, the pixel circuit 20 is further coupled to an unillustrated image processing circuit. The image processing circuit includes, for example, an analog-to-digital converter (ADC) and a digital signal processor (DSP).

The electric charge converted from the light in the pixel 10 is an analog signal. This analog signal is subjected to amplification processing in the pixel circuit 20. The ADC converts the analog signal outputted from the pixel circuit 20 into a digital signal. The DSP performs function processing on the digital signal. That is, the image processing circuit performs signal processing for image generation.

### (2) Configuration of Pixel 10

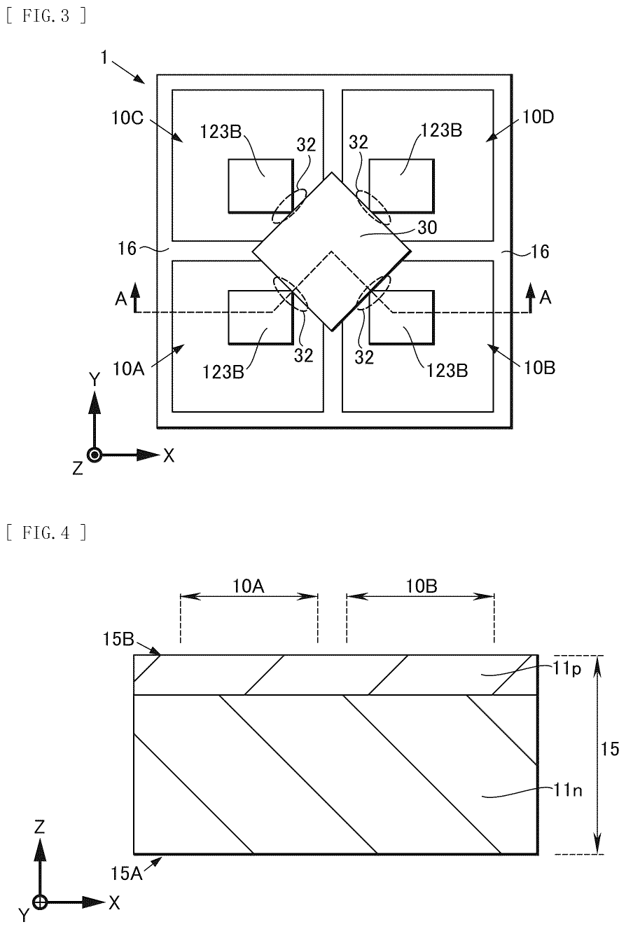

FIG. 3 illustrates an example of a schematic longitudinal cross-sectional configuration of the pixel 10. FIG. 4 illustrates an example of a schematic planar configuration of the pixel 10.

As illustrated in FIGS. 3 and 4, the unit pixel includes four pixels 10 arranged adjacent to each other. To describe this in detail, the unit pixel includes two pixels 10A and 10B arranged adjacent to each other in the arrow-X direction, and two pixels 10C and 10D arranged adjacent thereto in the arrow-Y direction and adjacent to each other in the arrow-X direction. That is, the pixels 10A to 10D are arranged in a matrix. Each of the pixels 10A to 10D is formed in a rectangular shape as viewed from the arrow-Z direction (hereinafter simply referred to as “in a plan view”).

Here, to aid understanding, the “pixels 10” are denoted by different reference numerals “pixel 10A” to “pixel 10D” for convenience. It is to be noted that the pixels 10 may be collectively simply referred to as “pixels 10” in some cases.

The pixels 10 are provided in a base 15. For example, a semiconductor substrate is used for the base 15. To describe this in more detail, a single-crystalline silicon (Si) substrate having a p-type semiconductor region (or a p-type well region) that is of a second electrically-conductive type is used for the base 15.

Further, each of the pixels 10A to 10D is provided in a region surrounded by a pixel separation region 16 in a plan view. The pixel separation region 16 is formed in a lattice pattern in a plan view.

### (3) Configuration of Pixel Separation Region 16

The pixel separation region 16 includes a groove 161, an embedded member 163, and an embedded member 164. The groove 161 is formed as a groove extending in a depth direction from a second surface 15B on a side in the arrow-Z direction of the base 15 to side of a first surface 15A opposite to the arrow-Z direction. Here, the first surface 15A serves as a light incident surface of the pixel 10.

The embedded member 163 is embedded in most of the groove 161 on a side of the first surface 15A of the groove 161. Here, for example, a polycrystalline Si film is used for the embedded member 163.

The embedded member 164 is embedded in the groove 161 on a side of the second surface 15B of the groove 161 and above the embedded member 163. For example, a silicon oxide (SiO) film, a silicon nitride (SiN) film, or the like is used for the embedded member 164.

That is, the pixel separation region 16 is configured by a trench isolation structure.

In addition, the pixel separation region 16 includes a pinning region 162 formed in the base 15 in a region along the embedded member 163 of the groove 161.

### (4) Configuration of Photoelectric Conversion Element 11

The photoelectric conversion element 11 of the pixel 10 is provided on the side of the first surface 15A of the base 15. The photoelectric conversion element 11 is provided for each of the pixels 10A to 10D. That is, one photoelectric conversion element 11 (corresponding to a “first photoelectric conversion element” according to the present technology) is provided for the pixel 10A. In addition, one photoelectric conversion element 11 (corresponding to a “second photoelectric conversion element” according to the present technology) is provided for the pixel 10B. Likewise, one photoelectric conversion element 11 is provided for the pixel 10C, and one photoelectric conversion element 11 is provided for the pixel 10D.

The photoelectric conversion element 11 is formed at a p-n junction between a p-type semiconductor region 11p and an n-type semiconductor region 11n. The p-type semiconductor region 11p is provided on the side of the second surface 15B of the base 15 in a region surrounded by the pixel separation region 16. Likewise, the n-type semiconductor region 11n is provided on the side of the first surface 15A of the base 15 in a region surrounded by the pixel separation region 16.

### (5) Configuration of Transistor 12

The transistor (a transfer transistor) 12 of the pixel 10 includes the n-type semiconductor region 11n as the one main electrode, an n-type semiconductor region 124 as the other main electrode, a gate insulating film 122, and a gate electrode 123.

The n-type semiconductor region 11n is the n-type semiconductor region 11n of the photoelectric conversion element 11.

The gate insulating film 122 is formed along an inner wall of a groove 121 reaching the n-type semiconductor region 11n from the second surface 15B of the base 15. For example, a monolayer film such as a SiO film or a SiN film, or a composite film of a combination of these is used for the gate insulating film 122.

The gate electrode 123 includes a vertical gate electrode section 123A and a gate electrode contact section 123B. The gate electrode 123 corresponds to a “first gate electrode” or a “second gate electrode” according to the present technology.

The vertical gate electrode section 123A is embedded in the groove 121 with the gate insulating film 122 interposed therebetween. For example, a polycrystalline Si film is used for the vertical gate electrode section 123A. This polycrystalline Si film includes an impurity that causes a decrease in resistance value.

The gate electrode contact section 123B is provided on the second surface 15B of the base 15. The gate electrode contact section 123B is in contact with and is electrically coupled to the vertical gate electrode section 123A. In addition, the gate electrode contact section 123B is electrically coupled to a wiring 7. The control signal TG is inputted from the wiring 7 to the gate electrode contact section 123B. For example, a polycrystalline Si film is used for the gate electrode contact section 123B, as with the vertical gate electrode section 123A.

The n-type semiconductor region 124 is provided on the side of the second surface 15B of the base 15 in a surface portion of the p-type semiconductor region 11p. The n-type semiconductor region 124 is provided at a position close to the pixel separation region 16. To describe this in detail, as illustrated in FIG. 3, the respective n-type semiconductor regions 124 of the four pixels 10A to 10D that construct the unit pixel are gathered at a middle position of the unit pixel.

### (6) Configuration of Shared Contact Section 30

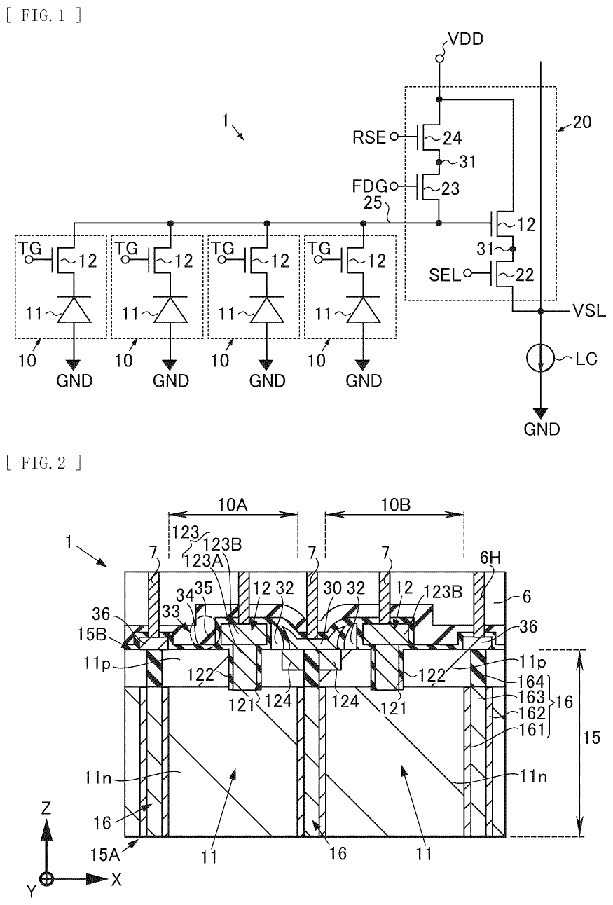

As illustrated in FIGS. 2 and 3, a shared contact (Shared Contact) section 30 is electrically coupled to the n-type semiconductor region 124 of the transistor 12. The shared contact section 30 is configured as a common contact section for a total of four n-type semiconductor regions 124 of the four pixels 10A to 10D that construct the unit pixel. The shared contact section 30 is configured as a portion of the FD 25 (refer to FIG. 1), and is electrically coupled to the pixel circuit 20 (refer to FIG. 1) through the wiring 7.

The shared contact section 30 is provided to overlap the pixel separation region 16 on the side of the second surface 15B of the base 15. To describe this in detail, the shared contact section 30 overlaps the pixel separation region 16, and extends from a position where the shared contact section 30 overlaps the pixel separation region 16 to each of the n-type semiconductor regions 124 of the pixels 10A to 10D to also overlap the n-type semiconductor regions 124. The shared contact section 30 is electrically coupled to each of the four n-type semiconductor regions 124 in an extended and overlapped region.

As illustrated in FIG. 2, in the first embodiment, a side surface of the shared contact section 30 on a side of the gate electrode 123 (the gate electrode contact section 123B) is formed in a shape that approaches the gate electrode 123 as moving away from the second surface 15B of the base 15 (in the arrow-Z direction). In other words, the side surface of the shared contact section 30 on the side of the gate electrode 123 protrudes toward the shared contact section 30, and is formed in such an arc-like cross-sectional shape as to ride on an upper portion of the gate electrode 123.

For example, a side surface of the shared contact section 30 on the side of the gate electrode 123 (corresponding to a “first gate electrode” according to the present technology) of the pixel 10A is formed in a shape that approaches the gate electrode (the first gate electrode) 123 as moving away from the second surface 15B. In addition, a side surface of the shared contact section 30 on the side of the gate electrode 123 (corresponding to a “second gate electrode” according to the present technology) of the pixel 10B is formed in a shape that approaches the gate electrode (the second gate electrode) 123 as moving away from the second surface 15B. The shape of the side surface of the shared contact section 30 is similar also in the pixel 10C and the pixel 10D.

For example, a polycrystalline Si film is used for the shared contact section 30. The polycrystalline Si film includes an impurity that causes a decrease in resistance value.

### (7) Configuration of Low-Dielectric Constant Region 32

As illustrated in FIGS. 2 and 3, a low-dielectric constant region 32 is provided between the gate electrode 123 of the transistor 12 of the pixel 10 and the FD 25 (refer to FIG. 1).

Detailed description is given of this point. The low-dielectric constant region 32 is provided between the gate electrode contact section 123B of the gate electrode 123 and the shared contact section 30 as a portion of the FD 25. The low-dielectric constant region 32 has a lower dielectric constant than that of a non-opposed region 33 surrounded by a broken line. The non-opposed region 33 is provided on a side opposite to the shared contact section 30 of the gate electrode contact section 123B.

Here, the non-opposed region 33 includes an insulating film 34 and an insulating film 35. The insulating film 34 covers a portion of a side surface of the gate electrode contact section 123B, and the insulating film 35 is stacked to cover the insulating film 34. The insulating film 34 is formed by, for example, a SiO film in the first embodiment. In addition, the insulating film 35 is formed by, for example, a SiN film.

The low-dielectric constant region 32 is a gap (Gap) in the first embodiment. To describe this in more detail, the low-dielectric constant region 32 is a gap containing a gas. Air is used as the gas. That is, the low-dielectric constant region 32 here is configured as an air-gap (Air-Gap).

The low-dielectric constant region 32 is provided between the gate electrode contact section 123B and the shared contact section 30 in such a manner, thereby decreasing a capacitance value of a parasitic capacitance in which the gate electrode contact section 123B serves as one electrode, the low-dielectric constant region 32 serves as a dielectric, and the shared contact section 30 serves as another electrode. That is, the capacitance value of the parasitic capacitance generated in each of the pixels 10A to 10D is decreased. As a result, it is possible to effectively reduce or prevent variations in capacitance value of the parasitic capacitance added to the FD 25.

It is to be noted that, in the present technology, there may be a vacuum inside the gap that is the low-dielectric constant region 32. In addition, the gap that is the low-dielectric constant region 32 may be filled with an inert gas such as a nitrogen gas (N₂) or an argon gas (Ar).

### (8) Configuration of Wiring 7

As illustrated in FIG. 2, the wiring 7 is provided in a contact hole 6H formed in the insulating film 34, the insulating film 35, and an interlayer insulating film 6 that cover each of the transistor 12 and the shared contact section 30. The contact hole 6H is a through hole formed in a thickness direction of the insulating film 34, the insulating film 35, and the interlayer insulating film 6.

Here, the interlayer insulating film 6 is formed by, for example, a SiO film. For example, a tungsten (W) film is used for the wiring 7. That is, the wiring 7 is formed as what is called a W plug.

One end of the wiring 7 on a side of the base 15 is electrically coupled to the transistor 12 with the shared contact section 30 interposed therebetween, as described above. Another end of the wiring 7 is electrically coupled to the pixel circuit 20 (refer to FIG. 1) not illustrated in the configuration diagram.

The pixel circuit 20 is provided in a substrate stacked on the interlayer insulating film 6 on a side opposite to the base 15. For example, a single-crystalline Si substrate is used for this substrate. That is, in the solid-state imaging device 1 according to the first embodiment, a two-stage structure is adopted in which the base 15 and the substrate are superimposed on each other. The base 15 includes the photoelectric conversion element 11 and the transistor (transfer transistor) 12. The substrate is stacked on the base 15, and the pixel circuit 20 is constructed in the substrate.

### [Manufacturing Method of Solid-State Imaging Device 1]

FIGS. 4 to 25 illustrate, step-by-step, an example of a manufacturing method of the solid-state imaging device 1 according to the first embodiment. It is to be noted that, in description of the manufacturing method, illustration and description of each of structures of the photoelectric conversion element 11 and the transistor (the transfer transistor) 12 are simplified or omitted.

First, as illustrated in FIG. 4, the base 15 is prepared. As described above, the base 15 is, for example, a single-crystalline Si substrate.

Next, a groove 161A is formed from a surface of the second surface 15B toward the first surface 15A of the base 15 in a formation region for the pixel separation region 16. The groove 161A has a shallower depth than that of the groove 161 to be formed later. For example, the groove 161A has such a depth as to reach the n-type semiconductor region 11n of the photoelectric conversion element 11. The groove 161A is formed with use of, for example, photolithography technology and etching technology. For example, anisotropic etching such as reactive ion etching (RIE: Reactive Ion Etching) is used for etching.

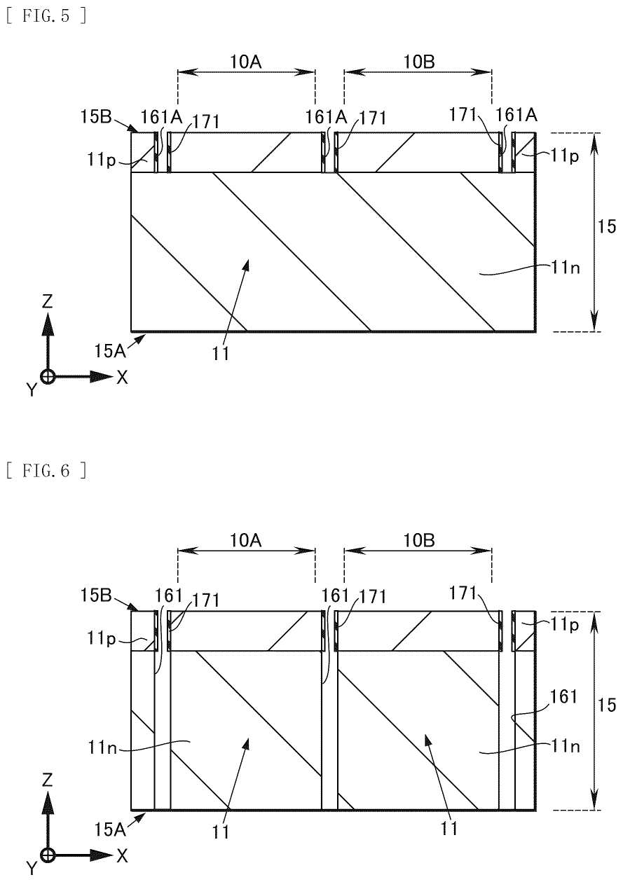

As illustrated in FIG. 5, a mask 171 is formed along an inner wall of the groove 161A. The mask 171 is used as an etching mask and an impurity doping mask. For example, a composite film in which a SiO film and a SiN film are stacked in order is used for the mask 171.

As illustrated in FIG. 6, the groove 161A is further dug with use of the mask 171 to form the groove 161. For example, anisotropic etching is used to form the groove 161.

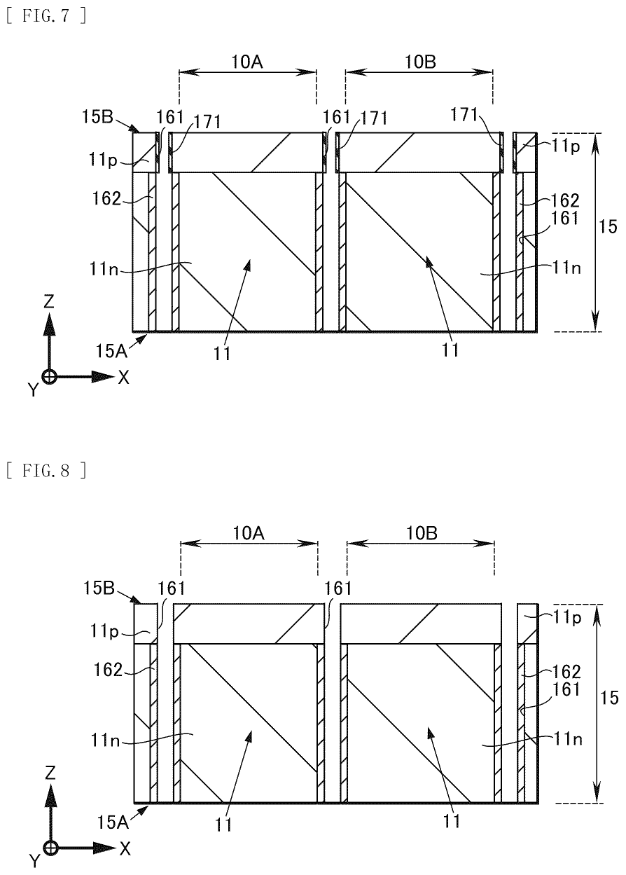

As illustrated in FIG. 7, the pinning region 162 is formed in a surface portion of the base 15 along an inner wall of the groove 161, specifically, a surface portion of the n-type semiconductor region 11n (refer to FIG. 3). The pinning region 162 is formed by doping the n-type semiconductor region 11n with a p-type impurity with use of the mask 171.

As illustrated in FIG. 8, the mask 171 is removed.

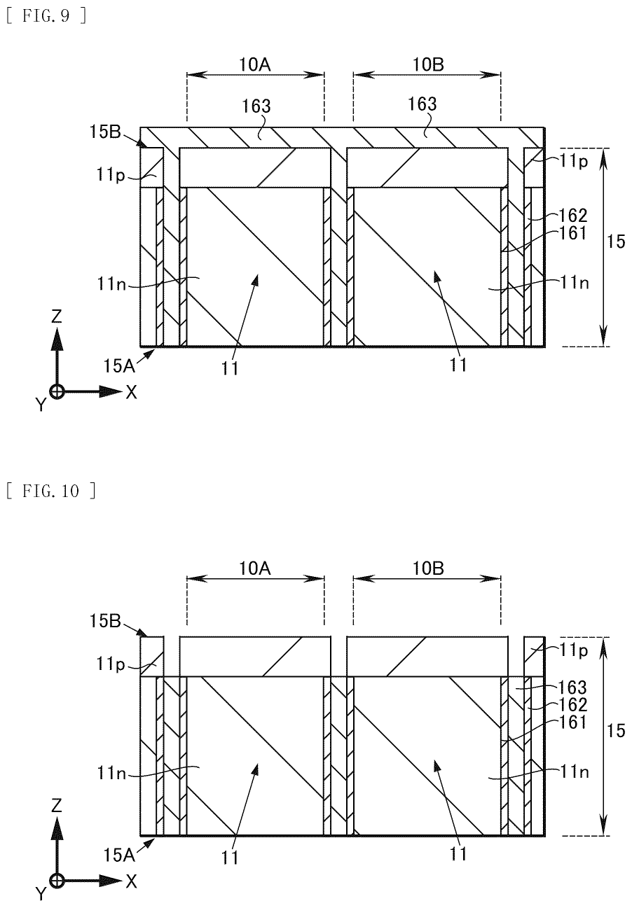

As illustrated in FIG. 9, the embedded member 163 is formed on the entire second surface 15B of the base 15. A polycrystalline Si film formed using, for example, a chemical vapor deposition (CVD: Chemical Vaper Deposition) method is used for the embedded member 163.

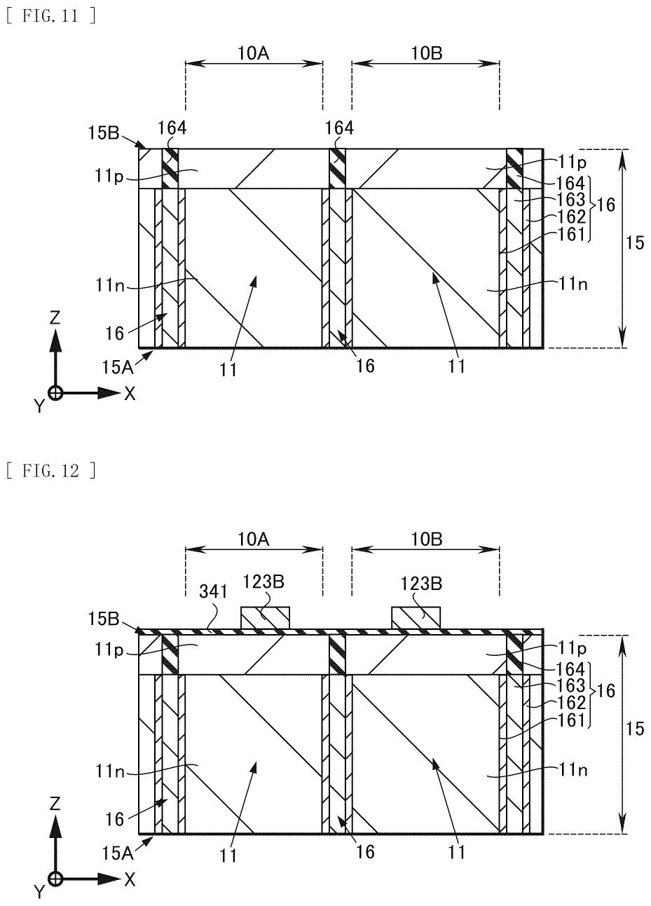

Subsequently, the entire surface of the base 15 is subjected to etching to remove the extra embedded member 163 on the second surface 15B. This causes the embedded member 163 to be embedded in the groove 161 as illustrated in FIG. 10.

As illustrated in FIG. 11, the embedded member 164 is further embedded on the embedded member 163 in the groove 161. A SiO film formed using, for example, a CVD method is used for the embedded member 164. As with the embedded member 163, the extra embedded member 164 is removed by etching after film formation.

When this step is completed, the pixel separation region 16 is completed.

An insulating film 341 is formed on the second surface 15B of the base 15 (refer to FIG. 12). This insulating film 341 is used as a gate insulating film of the transistor 12.

As illustrated in FIG. 12, the gate electrode contact section 123B is formed on the insulating film 341. Although not described here, the vertical gate electrode section 123A (refer to FIG. 2) of the transistor 12 has been already formed, and the gate electrode contact section 123B is formed on the vertical gate electrode section 123A to be electrically coupled to the vertical gate electrode section 123A. A polycrystalline Si film formed using, for example, a CVD method is used for the gate electrode contact section 123B.

When the gate electrode contact section 123B is formed, the gate electrode 123 having the vertical gate electrode section 123A and the gate electrode contact section 123B of the transistor 12 is completed.

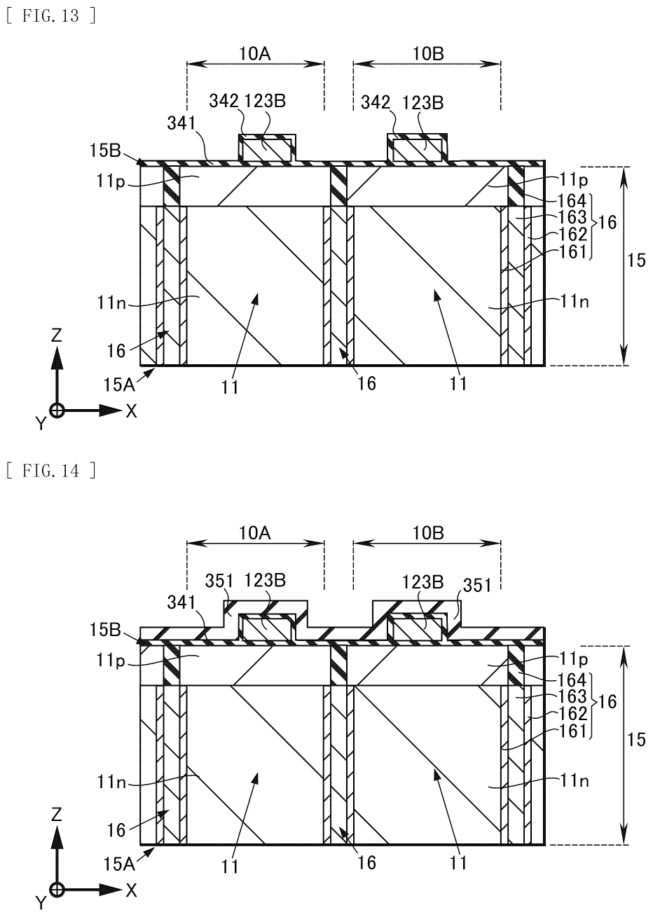

As illustrated in FIG. 13, an insulating film 342 is formed that covers a side surface and a top surface of the gate electrode contact section 123B. A SiO film formed using, for example, a CVD method is used for the insulating film 342.

Subsequently, as illustrated in FIG. 14, an insulating film 351 is formed on the side surface and the top surface of the gate electrode contact section 123B with the insulating film 342 interposed therebetween. A SiN film formed using, for example, a CVD method is used for the insulating film 351.

As illustrated in FIG. 15, an entire surface is subjected to etching, which causes the insulating film 351 on the side surface of the gate electrode contact section 123B to remain, and causes the insulating film 351 in another region to be removed. Anisotropic etching such as a RIE method is used for the etching. The insulating film 351 remaining on the side surface of the gate electrode contact section 123B is used as what is called a sidewall spacer.

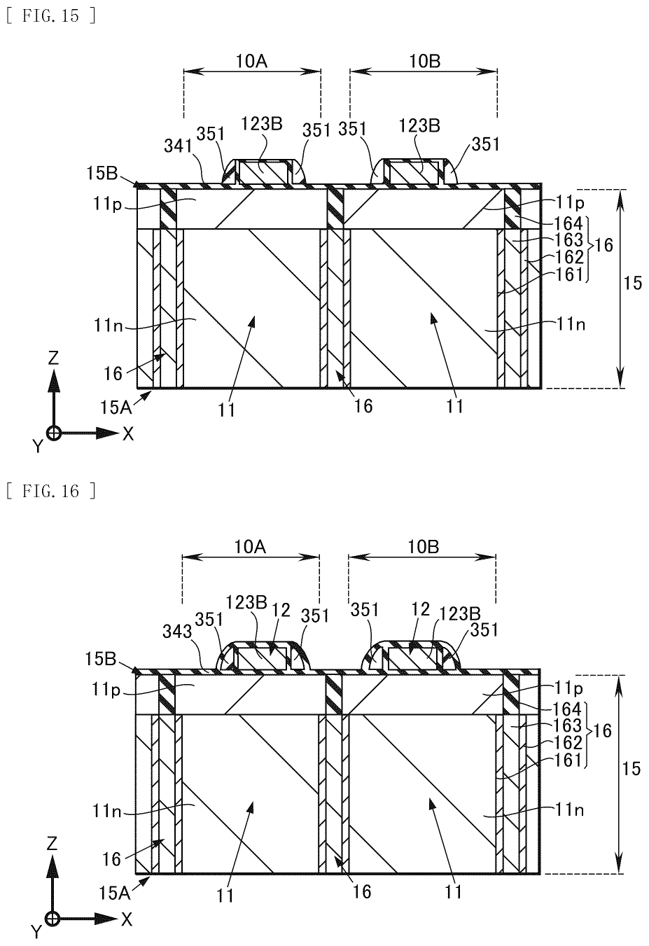

As illustrated in FIG. 16, an insulating film 343 is formed on the top surface of the gate electrode contact section 123B and a top surface of the insulating film 351. A SiO film formed using, for example, a CVD method is used for the insulating film 343.

As illustrated in FIG. 17, the insulating film 343 is used as a buffer film, and the n-type semiconductor region 124 to be used as the other main electrode of the transistor 12 is formed on a surface portion of the second surface 15B of the base 15. The n-type semiconductor region 124 is formed by doping the base 15 with an n-type impurity with use of, for example, an ion implantation method.

When the n-type semiconductor region 124 is formed, the transistor 12 is completed.

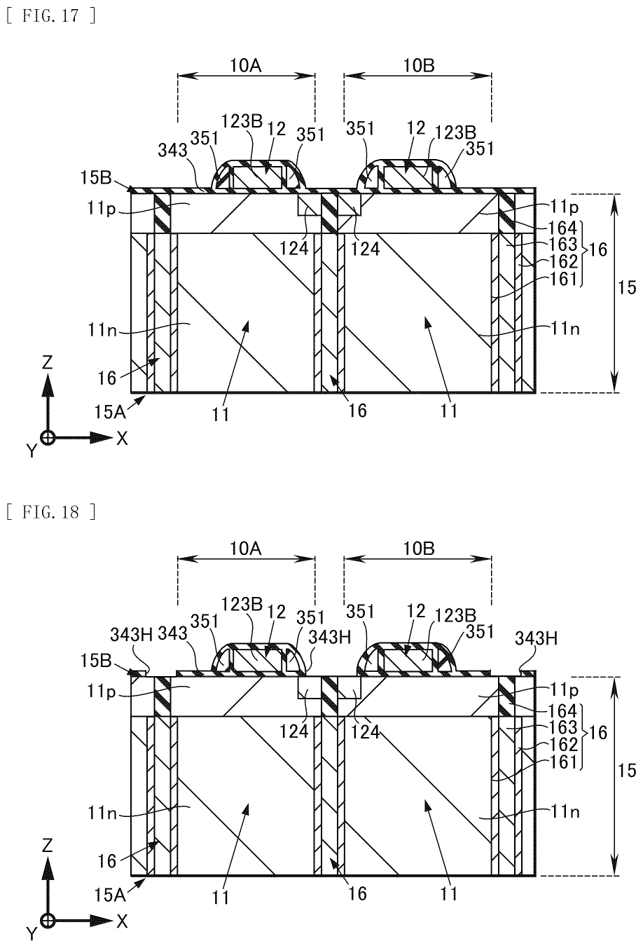

As illustrated in FIG. 18, an opening 343H is formed in the insulating film 343 in a region overlapping the n-type semiconductor region 124 and the pixel separation region 16. The opening 343H is formed with use of photolithography technology and etching technology.

As illustrated in FIG. 19, an electrically conductive film 301 is formed on the entire surface of the base 15 including a top surface of the insulating film 343. The electrically conductive film 301 includes a material for forming the shared contact section 30. A polycrystalline Si film formed using, for example, a CVD method is used for the electrically conductive film 301.

Subsequently, the electrically conductive film 301 is doped with a p-type impurity in a portion corresponding to the opening 343H overlapping the pixel separation region 16 except for a formation region for the shared contact section 30 to form a p-type electrically conductive film 36. The p-type electrically conductive film 36 is used, for example, as a path for supplying a reference voltage.

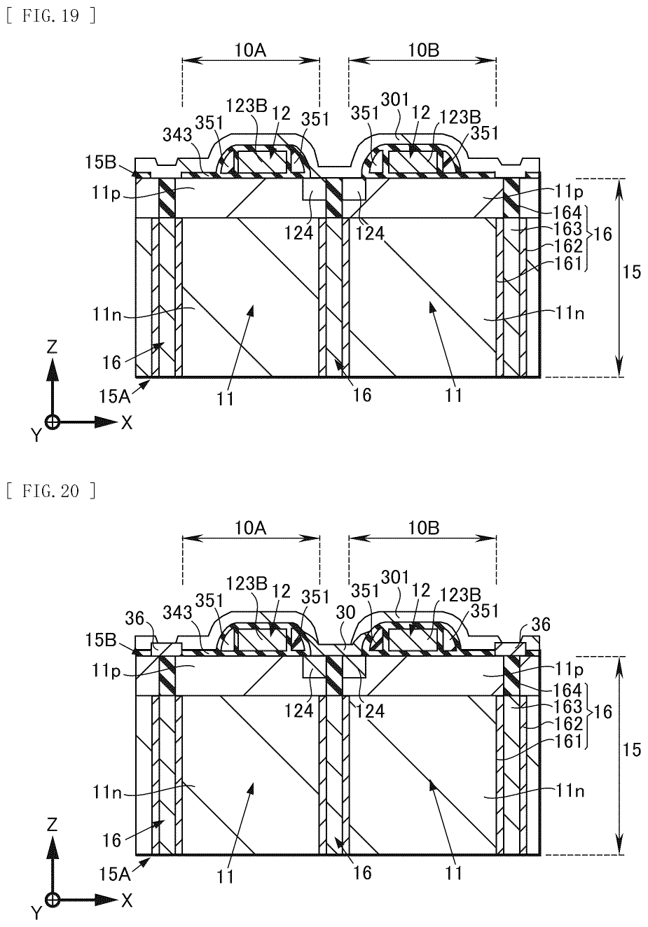

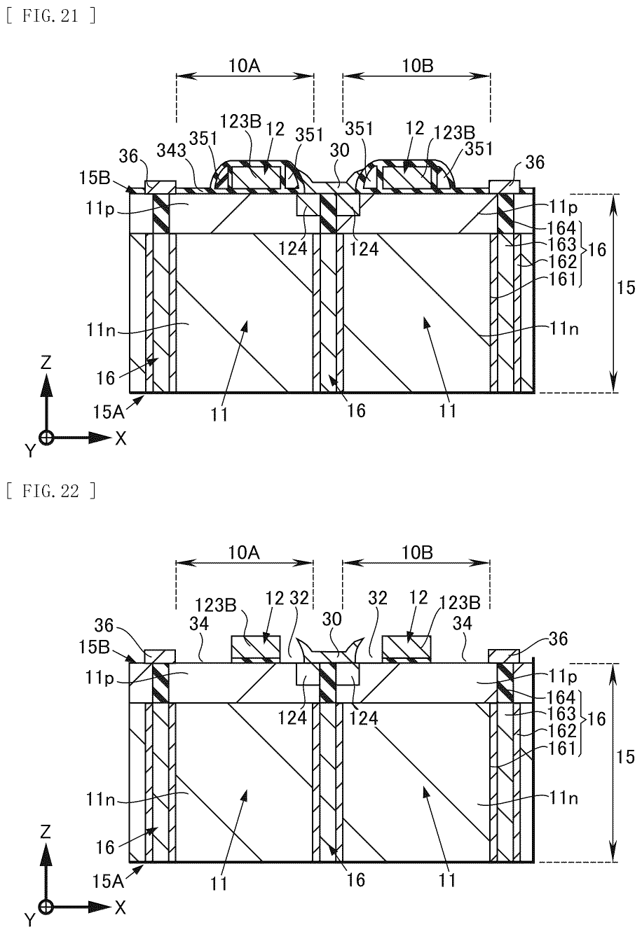

As illustrated in FIG. 20, the electrically conductive film 301 is doped with an n-type impurity in the formation region for the shared contact section 30. When the electrically conductive film 301 is doped with the n-type impurity, the shared contact section 30 is substantially formed.

As illustrated in FIG. 21, the electrically conductive film 301 is subjected to patterning to remove the extra electrically conductive film 301, thereby forming the shared contact section 30 and the p-type electrically conductive film 36. Photolithography technology and etching technology are used for the patterning.

As illustrated in FIG. 22, the insulating film 343 and the insulating film 351 are selectively removed. Etching technology is used for this selective removal.

Here, as described above, the insulating film 351 is formed as a sidewall spacer, and is removed, thereby forming the low-dielectric constant region 32 that becomes a gap between the gate electrode contact section 123B and the shared contact section 30. That is, the low-dielectric constant region 32 is formed by forming a sidewall spacer on the side surface of the gate electrode contact section 123B and using a gap in which the sidewall spacer is removed.

For example, when exposure to atmosphere is performed during a manufacturing step, the gap that is the low-dielectric constant region 32 is filled with air. In addition, when a vacuum is drawn inside a furnace during a manufacturing step, a vacuum is created inside the gap that is the low-dielectric constant region 32. Furthermore, when a carrier gas, e.g., an inert gas, to flow into the furnace during a manufacturing step is used, the gap that is the low-dielectric constant region 32 is filled with the inert gas.

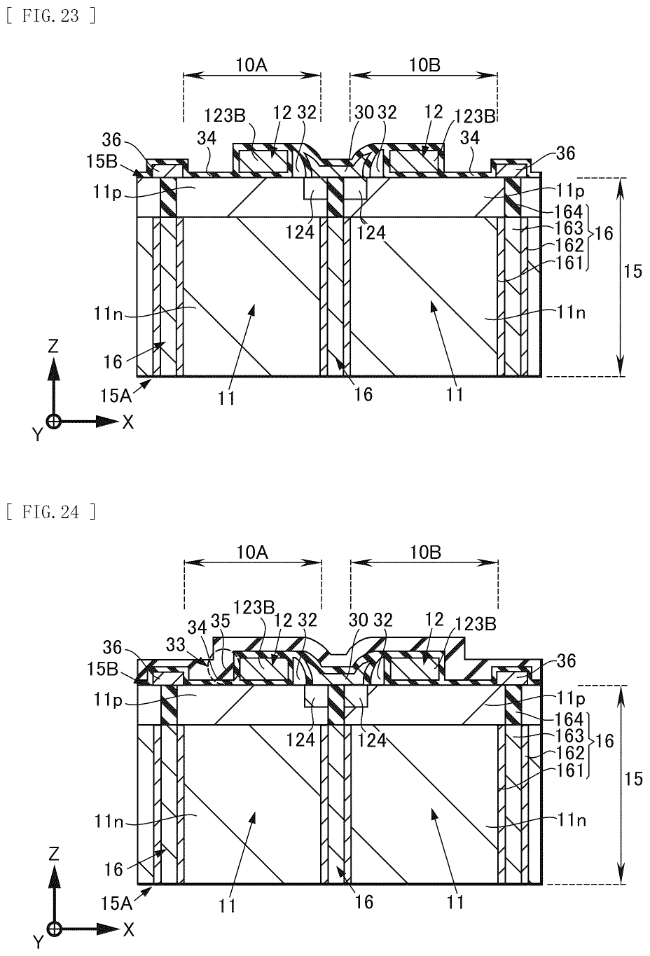

Subsequently, as illustrated in FIG. 23, the insulating film 34 that covers the shared contact section 30 is formed on the entire second surface 15B of the base 15. Furthermore, as illustrated in FIG. 24, the insulating film 35 is formed on the insulating film 34.

Here, the non-opposed region 33 including the insulating film 34 and the insulating film 35 is formed in a region other than a region where the low-dielectric constant region 32 is formed on the side surface of the gate electrode contact section 123B. The low-dielectric constant region 32 has a smaller dielectric constant than a dielectric constant of the non-opposed region 33.

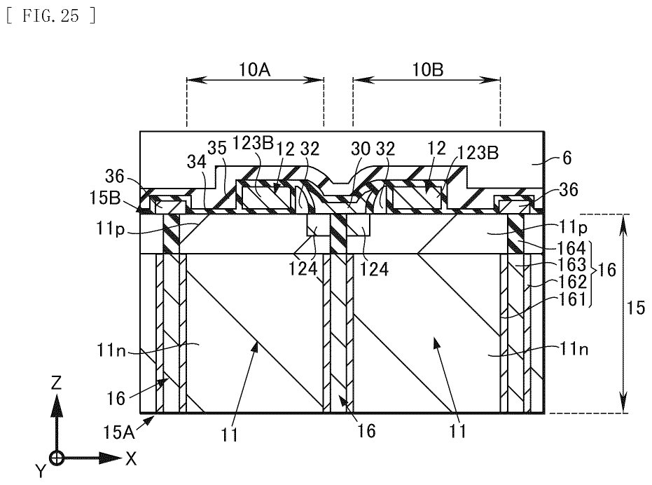

Next, as illustrated in FIG. 25, the interlayer insulating film 6 is formed on the insulating film 35.

Subsequently, the contact hole 6H is formed in the interlayer insulating film 6, and as illustrated in FIG. 2 described above, the wiring 7 is formed in the contact hole 6H.

It is to be noted that illustration and description of the manufacturing method of the pixel circuit 20 (refer to FIG. 1) and the like are omitted.

When a series of these manufacturing steps ends, the solid-state imaging device 1 according to the first embodiment is completed, and the manufacturing method ends.

### [Workings and Effects]

The solid-state imaging device 1 according to the first embodiment includes the pixel (a first pixel) 10, the transistor (a first transistor) 12, and the FD 25.

The pixel 10 is, for example, the pixel 10A. The pixel 10 is provided on the side of the first surface 15A, which is a light incident side, of the base 15, and includes the photoelectric conversion element (a first photoelectric conversion element) 11 that converts light into electric charge. The transistor 12 is provided on the side of the second surface 15B opposite to the first surface 15A of the base 15 at a position corresponding to the pixel 10. The transistor 12 includes the gate electrode (a first gate electrode) 123, and one of the pair of main electrodes is electrically coupled to the photoelectric conversion element 11. The FD 25 is provided on the side of the second surface 15B of the base 15, and is electrically coupled to the n-type semiconductor region 124, which is the other main electrode, of the transistor 12.

As illustrated in FIGS. 2 and 3, the solid-state imaging device 1 further includes the low-dielectric constant region 32. The low-dielectric constant region 32 is provided between the FD 25 and the gate electrode 123 opposed to the FD 25. The low-dielectric constant region 32 has a lower dielectric constant than that of the non-opposed region 33 that is not opposed to the FD 25.

Such a configuration makes it possible to reduce the capacitance value of the parasitic capacitance in which the gate electrode contact section 123B serves as one electrode, the low-dielectric constant region 32 serves as a dielectric, and the FD 25 serves as another electrode. That is, the capacitance value of the parasitic capacitance added to the FD 25 is reduced, which makes it possible to reduce variations in the capacitance value. Accordingly, in the solid-state imaging device 1, it is possible to suppress signal variations and signal delay due to the parasitic capacitance.

In addition, as illustrated in FIGS. 1 to 3, the solid-state imaging device 1 further includes the pixel (a second pixel) 10 and the transistor (a second transistor) 12.

The pixel 10 is, for example, the pixel 10B (or the pixel 10C). The pixel 10 is provided adjacent to, for example, the pixel 10A as the first pixel. The pixel 10 is provided on the side of the first surface 15A of the base 15, and includes the photoelectric conversion element (a second photoelectric conversion element) 11 that converts light into electric charge. The transistor 12 is provided on the side of the second surface 15B of the base 15 at a position corresponding to the pixel 10. The transistor 12 includes the gate electrode (a second gate electrode) 123, and one of the pair of main electrodes is electrically coupled to the photoelectric conversion element 11, and the FD 25 is electrically coupled to the n-type semiconductor region 124 that is the other main electrode.

Here, the solid-state imaging device 1 further includes the low-dielectric constant region 32 between the FD 25 and the gate electrode 123 opposed to the FD 25.

Such a configuration makes it possible to reduce the capacitance value of the parasitic capacitance in which the gate electrode 123 serves as one electrode, the low-dielectric constant region 32 serves as a dielectric, and the FD 25 serves as another electrode. That is, the capacitance value of the parasitic capacitance added to the FD 25 is reduced, which makes it possible to reduce variations in the capacitance value. Accordingly, in the solid-state imaging device 1, it is possible to suppress signal variations and signal delay due to the parasitic capacitance.

In addition, as illustrated in FIGS. 2 and 3, the solid-state imaging device 1 further includes the pixel separation region 16 and the shared contact section 30.

The pixel separation region 16 is provided between two pixels (the first pixel and the second pixel) 10 adjacent to each other in the base 15 to electrically and optically separate the pixels 10 from each other. In the first embodiment, the pixel separation region 16 has the groove 161, the embedded member 163, and the embedded member 164. The groove 161 is formed in the depth direction of the base 15, and the embedded member 163 and the embedded member 164 are embedded in the groove 161.

The shared contact section 30 is provided to overlap the pixel separation region 16 on the side of the second surface 15B of the base 15, and electrically couple, for example, the other main electrode (the n-type semiconductor region 124) of the transistor (the first transistor) 12 of the pixel 10A and the other main electrode (the n-type semiconductor region 124) of the transistor (the second transistor) 12 of the pixel 10B to each other. In addition, the FD 25 is electrically coupled to the shared contact section 30.

Furthermore, the low-dielectric constant region 32 is provided between the gate electrode 123 and the shared contact section 30.

Accordingly, it is possible to reduce the capacitance value of the parasitic capacitance between the gate electrode 123 and the shared contact section 30.

In addition, in the solid-state imaging device 1, as illustrated in FIG. 2, the side surface of the shared contact section 30 on a side of each of the gate electrodes (the first gate electrode and the second gate electrode) 123 is formed in a shape that approaches the gate electrode 123 as moving away from the second surface 15B of the base 15 in the arrow-Z direction.

To describe this in detail, as illustrated in FIG. 21 for the manufacturing method, the shared contact section 30 is formed in a shape covering the insulating film 351 as a sidewall spacer on a side surface of the gate electrode 123 (specifically, the gate electrode contact section 123B). Thereafter, as illustrated in FIG. 22, the low-dielectric constant region 32 is formed using a gap in which the insulating film 351 is selectively removed.

Accordingly, it is possible to simply form the low-dielectric constant region 32, and it is possible to easily reduce the capacitance value of the parasitic capacitance.

In addition, in the solid-state imaging device 1, as illustrated in FIG. 2, the low-dielectric constant region 32 is a gap. In addition, there is a vacuum in the gap of the low-dielectric constant region 32. Alternatively, the gap of the low-dielectric constant region 32 is filled with air or an inert gas.

This allows the low-dielectric constant region 32 to have a simple configuration, which makes it possible to easily reduce the capacitance value of the parasitic capacitance.

### 2. Second Embodiment

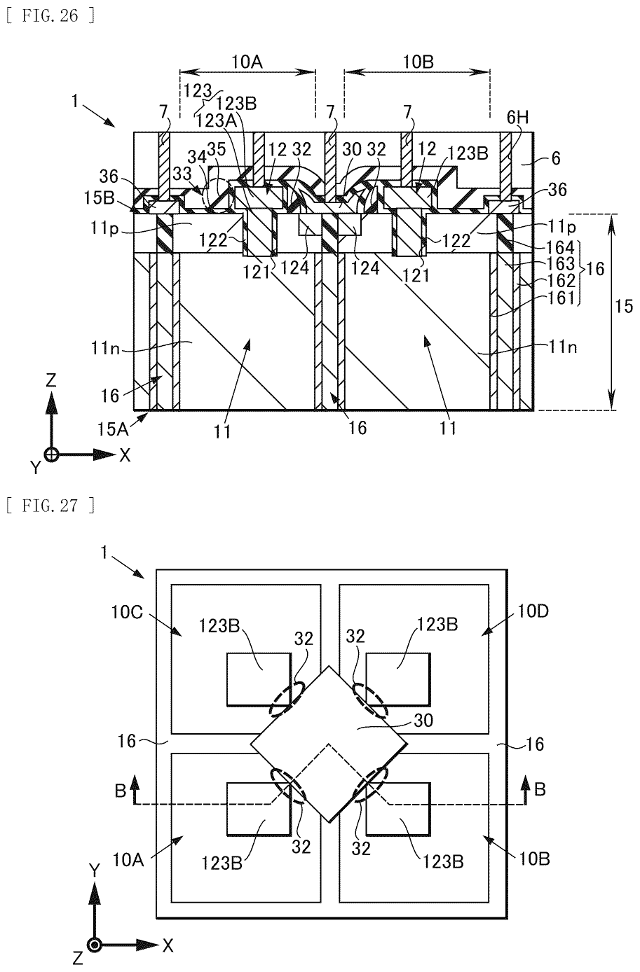

Description is given of the solid-state imaging device 1 according to the second embodiment of the present disclosure with reference to FIGS. 26 and 27. It is to be noted that, in the second embodiment and the subsequent embodiments, components the same or substantially the same as the components of the solid-state imaging device 1 according to the first embodiment are denoted by the same reference numerals, and redundant descriptions are omitted.

### [Configuration of Solid-State Imaging Device 1]

FIG. 26 illustrates an example of a schematic longitudinal cross-sectional configuration of the pixel 10. FIG. 27 illustrates an example of a schematic planar configuration of the pixel 10.

As illustrated in FIGS. 26 and 27, in the solid-state imaging device 1 according to the second embodiment, the low-dielectric constant region 32 of the solid-state imaging device 1 according to the first embodiment is formed by a low-dielectric constant material. The low-dielectric constant material has a lower dielectric constant than the dielectric constant of the non-opposed region 33.

To describe this in detail, in the example described above, the non-opposed region 33 is formed in which the insulating film 34 is a SiO film and the insulating film 35 is a SiN film. Accordingly, the low-dielectric constant region 32 is formed by a monolayer film of a SiO film or a carbon-doped silicon oxide (SiOC) film, or a composite film in which these films are stacked.

Components other than the above-described components are the same or substantially the same as the components of the solid-state imaging device 1 according to the first embodiment.

### [Workings and Effects]

In the solid-state imaging device 1 according to the second embodiment illustrated in FIGS. 26 and 27, it is possible to obtain workings and effects similar to the workings and effects obtained by the solid-state imaging device 1 according to the first embodiment.

### 3. Third Embodiment

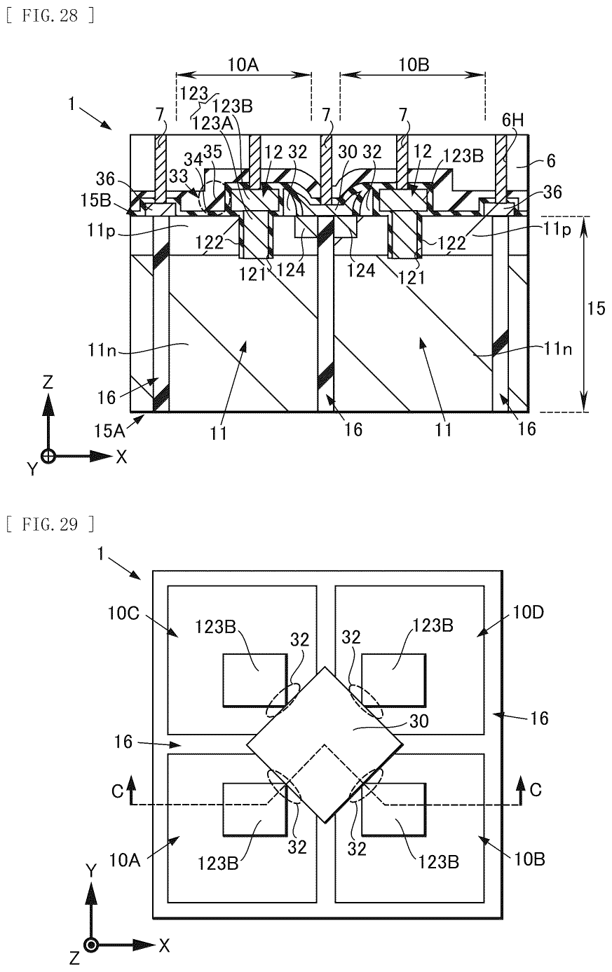

Description is given of the solid-state imaging device 1 according to the third embodiment of the present disclosure with reference to FIGS. 28 and 29.

### [Configuration of Solid-State Imaging Device 1]

FIG. 28 illustrates an example of a schematic longitudinal cross-sectional configuration of the pixel 10. FIG. 29 illustrates an example of a schematic planar configuration of the pixel 10.

As illustrated in FIGS. 28 and 29, in the solid-state imaging device 1 according to the third embodiment, the configuration of the pixel separation region 16 is changed in the solid-state imaging device 1 according to the first embodiment or the second embodiment. To describe this in detail, the pixel separation region 16 includes an insulator region instead of a structure including the groove 161, the embedded member 163, and the embedded member 164. The insulator region is formed by doping the base 15 with an impurity with use of, for example, an ion implantation method.

Components other than the above-described components are the same or substantially the same as the components of the solid-state imaging device 1 according to the first embodiment or the second embodiment.

### [Workings and Effects]

In the solid-state imaging device 1 according to the third embodiment illustrated in FIGS. 28 and 29, it is possible to obtain workings and effects similar to the workings and effects obtained by the solid-state imaging device 1 according to the first embodiment or the second embodiment.

In addition, in the solid-state imaging device 1, as illustrated in FIGS. 28 and 29, the pixel separation region 16 includes the insulator region. Accordingly, it is possible to simply configure the pixel separation region 16, which makes it possible to simply achieve the structure of the solid-state imaging device 1.

### 4. Fourth Embodiment

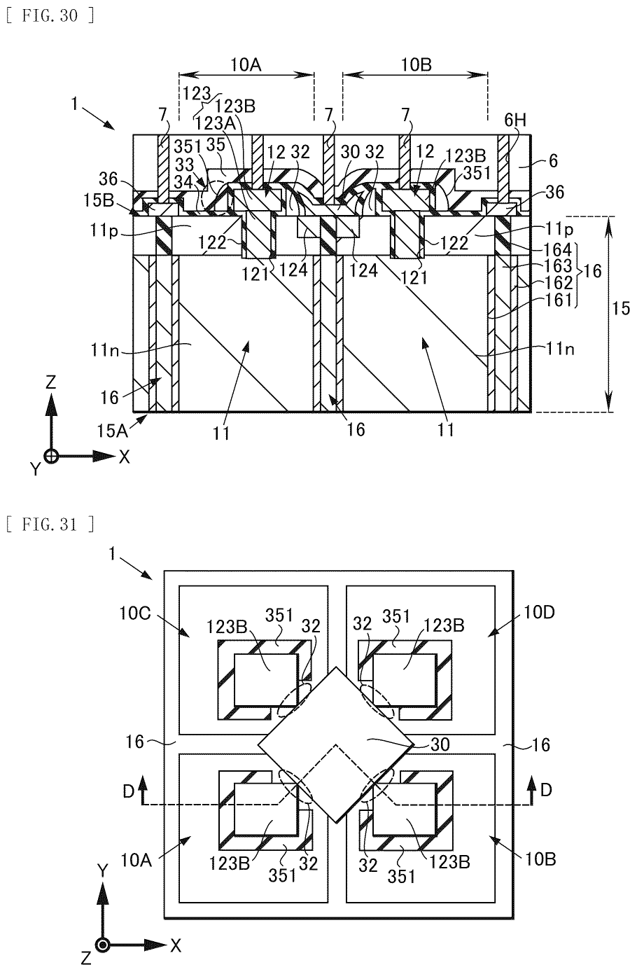

Description is given of the solid-state imaging device 1 according to the fourth embodiment of the present disclosure with reference to FIGS. 30 and 31.

### [Configuration of Solid-State Imaging Device 1]

FIG. 30 illustrates an example of a schematic longitudinal cross-sectional configuration of the pixel 10. FIG. 31 illustrates an example of a schematic planar configuration of the pixel 10.

As illustrated in FIGS. 30 and 31, the solid-state imaging device 1 according to the fourth embodiment is formed in a state in which the insulating film 351 remains in the non-opposed region 33 in the solid-state imaging device 1 according to the first embodiment or the second embodiment. The insulating film 351 is a sidewall spacer formed on the side surface of the gate electrode contact section 123B of the transistor 12.

That is, in the manufacturing method of the solid-state imaging device 1, in a step illustrated in FIG. 22 described above, the insulator 351 between the gate electrode contact section 123B and the shared contact section 30 is selectively removed, but the insulator 351 between the gate electrode contact section 123B and the non-opposed region 33 is not removed.

Components other than the above-described components are the same or substantially the same as the components of the solid-state imaging device 1 according to the first embodiment or the second embodiment. In addition, the solid-state imaging device 1 according to the fourth embodiment may be applied to the solid-state imaging device 1 according to the third embodiment.

### [Workings and Effects]

In the solid-state imaging device 1 according to the fourth embodiment illustrated in FIGS. 30 and 31, it is possible to obtain workings and effects similar to the workings and effects obtained by the solid-state imaging device 1 according to the first embodiment or the second embodiment.

In addition, in the solid-state imaging device 1, the insulating film 351 as a sidewall spacer is provided on a side surface of the non-opposed region 33 of the gate electrode 123 (the gate electrode contact section 123B). The low-dielectric constant region 32 has a lower dielectric constant than that of the insulating film 351.

In the solid-state imaging device 1 configured as described above, the capacitance value of the parasitic capacitance added to the FD 25 is reduced, which makes it possible to suppress signal variations and signal delay due to the parasitic capacitance.

### 5. Fifth Embodiment

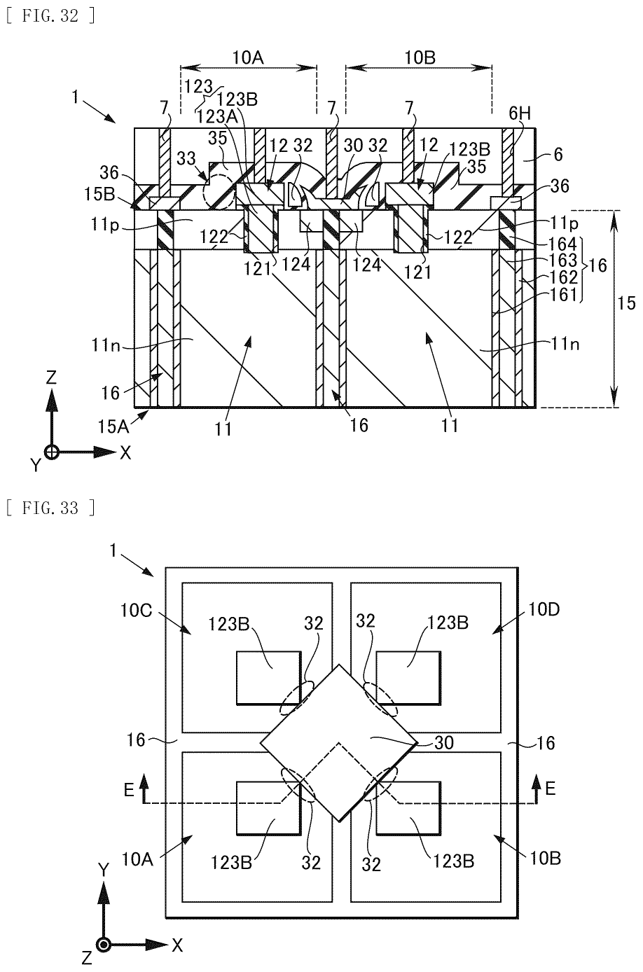

Description is given of the solid-state imaging device 1 according to the fifth embodiment of the present disclosure with reference to FIGS. 32 and 33.

### [Configuration of Solid-State Imaging Device 1]

FIG. 32 illustrates an example of a schematic longitudinal cross-sectional configuration of the pixel 10. FIG. 33 illustrates an example of a schematic planar configuration of the pixel 10.

As illustrated in FIGS. 32 and 33, in the solid-state imaging device 1 according to the fifth embodiment, the insulating film 35 is formed on the gate electrode contact section 123B of the transistor 12 and on the shared contact section 30. The insulating film 34 is omitted (refer to FIG. 2).

As described above, the insulating film 35 is formed by, for example, a SiN film. Embeddability of the insulating film 35 is poorer than embeddability of an SiO film, for example.

Components other than the above-described components are the same or substantially the same as the components of the solid-state imaging device 1 according to the first embodiment or the second embodiment. In addition, the solid-state imaging device 1 according to the fifth embodiment may be applied to the solid-state imaging device 1 according to the third embodiment or the fourth embodiment.

### [Workings and Effects]

In the solid-state imaging device 1 according to the fifth embodiment illustrated in FIGS. 32 and 33, it is possible to obtain workings and effects similar to the workings and effects obtained by the solid-state imaging device 1 according to the first embodiment or the second embodiment

### 6. Sixth Embodiment

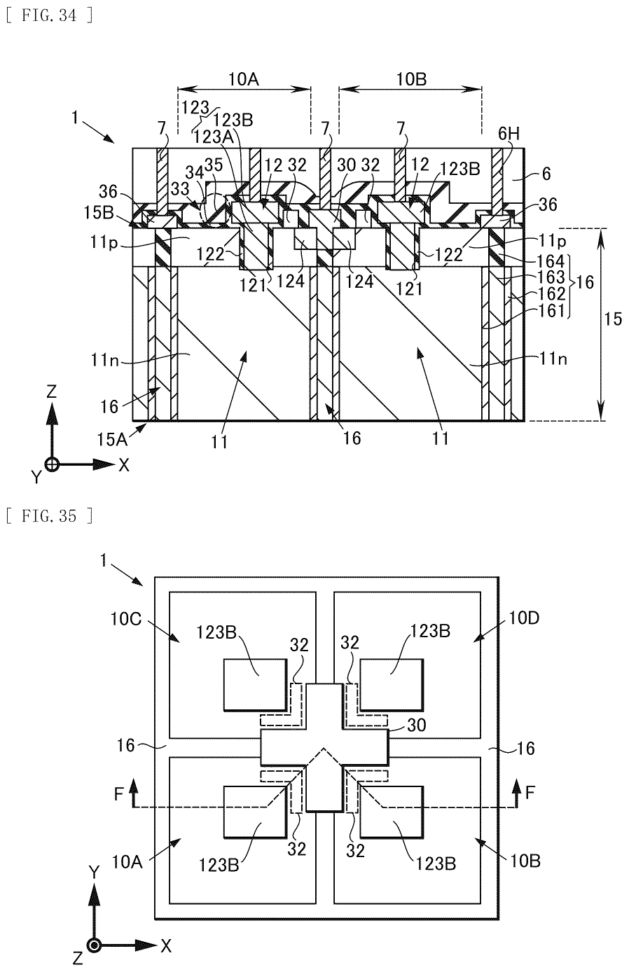

Description is given of the solid-state imaging device 1 according to the sixth embodiment of the present disclosure with reference to FIGS. 34 to 59.

### [Configuration of Solid-State Imaging Device 1]

FIG. 34 illustrates an example of a schematic longitudinal cross-sectional configuration of the pixel 10. FIG. 35 illustrates an example of a schematic planar configuration of the pixel 10.

As illustrated in FIGS. 34 and 35, in the solid-state imaging device 1 according to the sixth embodiment, a portion of the shared contact section 30 is embedded in the groove 161 of the pixel separation region 16 in the solid-state imaging device 1 according to the first embodiment or the second embodiment.

To describe this in detail, the portion of the shared contact section 30 is embedded in an upper portion of the groove 161, and further is electrically coupled to a side surface of the n-type semiconductor region 124 of the transistor 12 of the adjacent pixel 10. It is sufficient if the portion of the shared contact section 30 is embedded to about a junction depth of the n-type semiconductor region 124.

### [Manufacturing Method of Solid-State Imaging Device 1]

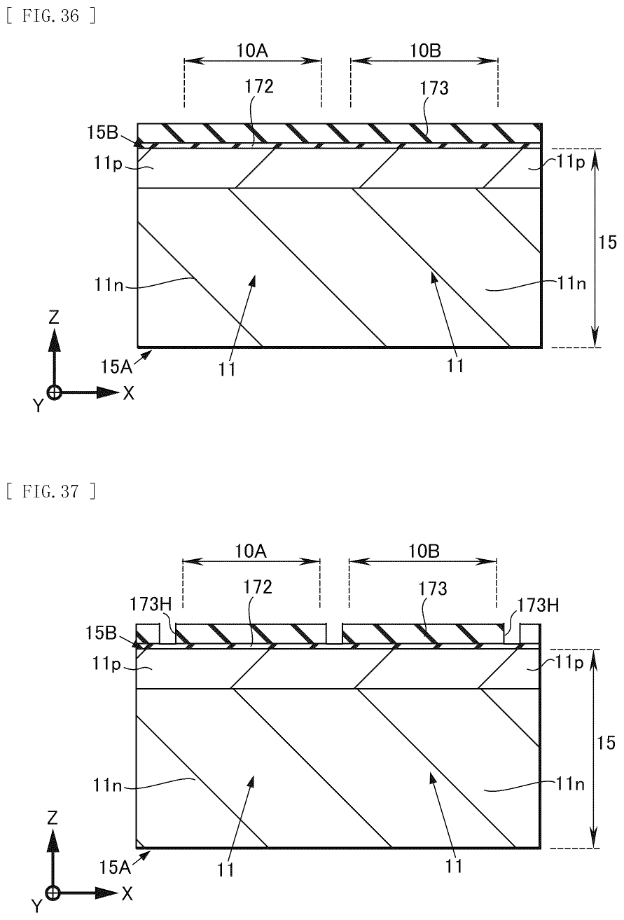

FIGS. 36 to 59 illustrate, step-by-step, an example of a manufacturing method of the solid-state imaging device 1 according to the sixth embodiment. It is to be noted that, in description of the manufacturing method, illustration and description of each of respective cross-sectional structures of the photoelectric conversion element 11 and the transistor (the transfer transistor) 12 are simplified or omitted.

First, as with a step illustrated in FIG. 4 of the manufacturing method of the solid-state imaging device 1 according to the first embodiment (hereinafter simply referred to as a “first manufacturing method”), the base 15 is prepared.

As illustrated in FIG. 36, a mask 172 and a mask 173 are formed in order on the second surface 15B of the base 15. The mask 172 is used, for example, as an etching stopper, and is formed by a SiN film. The mask 173 is used, for example, as an etching hard mask, and is formed by a SiO film.

As illustrated in FIG. 37, an opening 173H is formed in the mask 173 in the formation region for the pixel separation region 16. The opening 173H is formed with use of, for example, photolithography technology and etching technology.

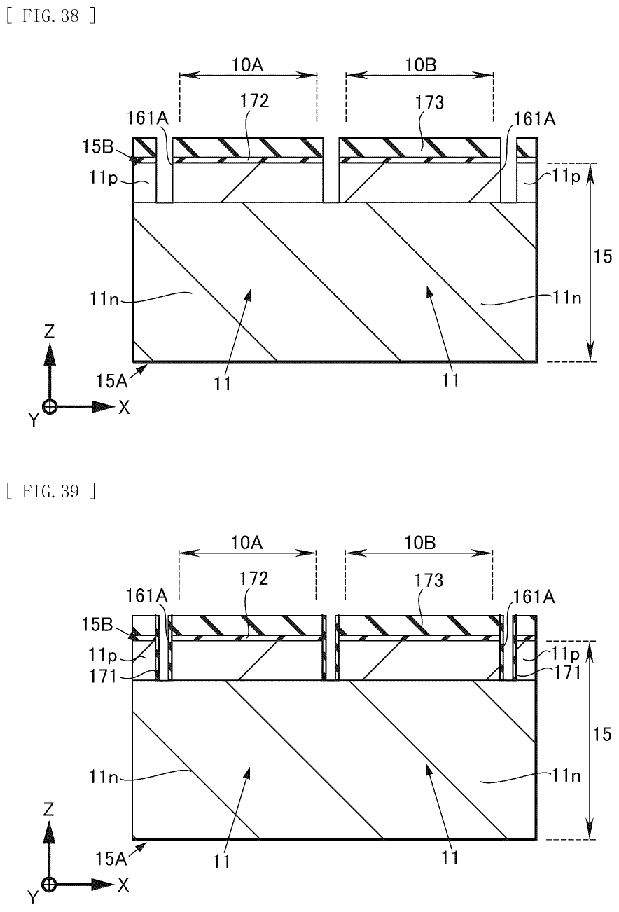

As illustrated in FIG. 38, the groove 161A is formed with use of the mask 173 from the surface of the second surface 15B toward the first surface 15A of the base 15. The groove 161A has a shallow depth. The groove 161A is formed with use of, for example, etching technology.

As with a step illustrated in FIG. 5 of the first manufacturing method, as illustrated in FIG. 39, the mask 171 is formed along the inner wall of the groove 161A.

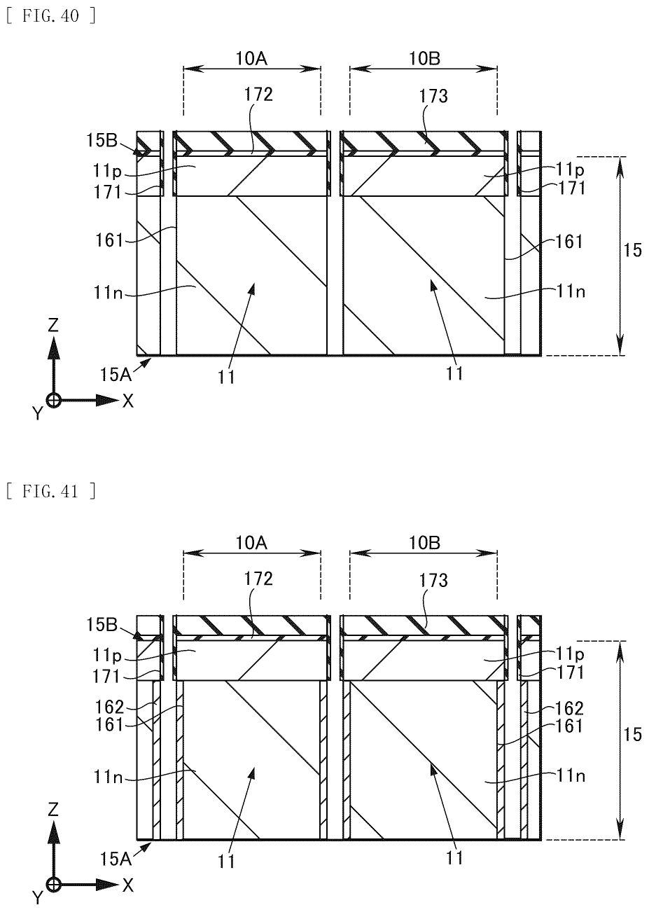

As with a step illustrated in FIG. 6 of the first manufacturing method, as illustrated in FIG. 40, the groove 161A is further dug with use of the mask 171 to form the groove 161.

As with a step illustrated in FIG. 7 of the first manufacturing method, as illustrated in FIG. 41, the pinning region 162 is formed in the surface portion of the base 15 along the inner wall of the groove 161.

### Thereafter, as illustrated in FIG. 42, the mask 171 is removed.

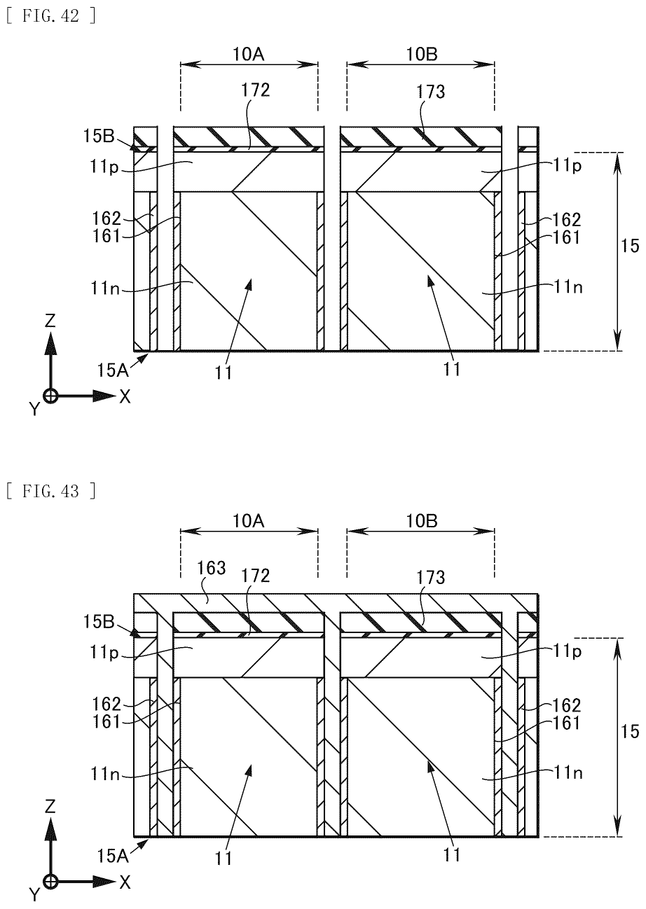

As with a step illustrated in FIG. 9 of the first manufacturing method, as illustrated in FIG. 43, the embedded member 163 is formed on the entire second surface 15B of the base 15. Here, the embedded member 163 is formed on the mask 173.

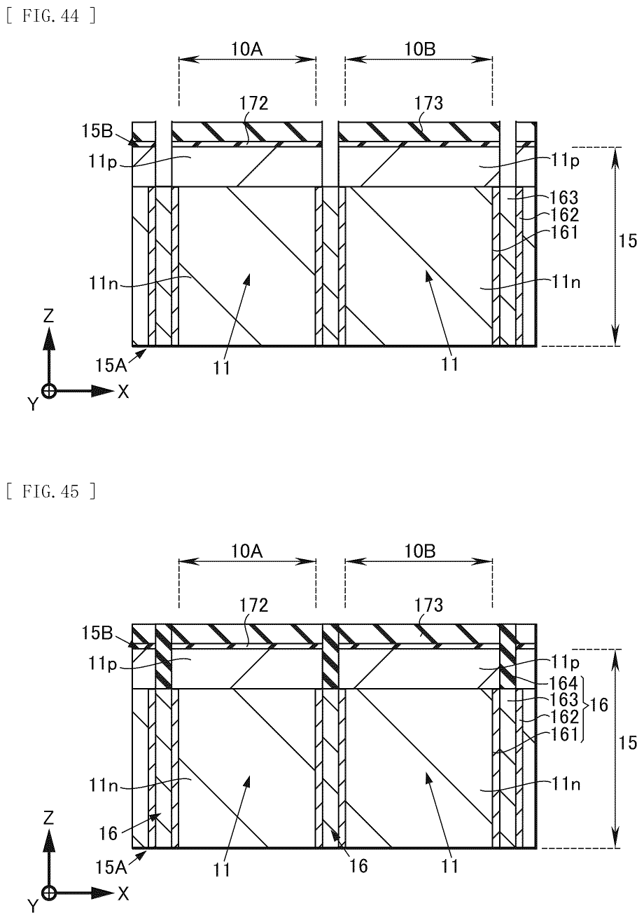

Subsequently, the entire surface of the base 15 is subjected to etching to remove the extra embedded member 163 on the mask 173. Accordingly, as illustrated in FIG. 44, the embedded member 163 is embedded in the groove 161.

As with a step illustrated in FIG. 11 of the first manufacturing method, as illustrated in FIG. 45, the embedded member 164 is further embedded on the embedded member 163 in the groove 161. After film formation of the embedded member 164, the extra embedded member 164 on the mask 173 is removed.

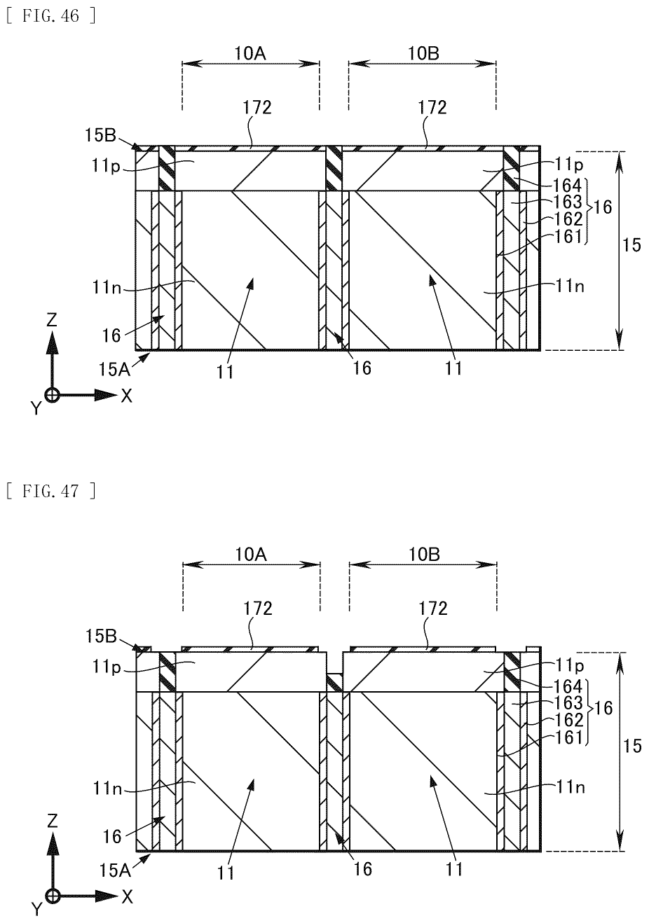

Subsequently, as illustrated in FIG. 46, the mask 173 and the embedded member 164 remaining in the opening 173H are removed. Etching technology is used for this removal.

Furthermore, a portion of the embedded member 164 is further removed with use of the mask 172. A top surface of the embedded member 164 is dug inside the base 15 deeper than the second surface 15B of the base 15. Etching technology is used to remove the embedded member 164.

When this step is completed, the pixel separation region 16 is completed.

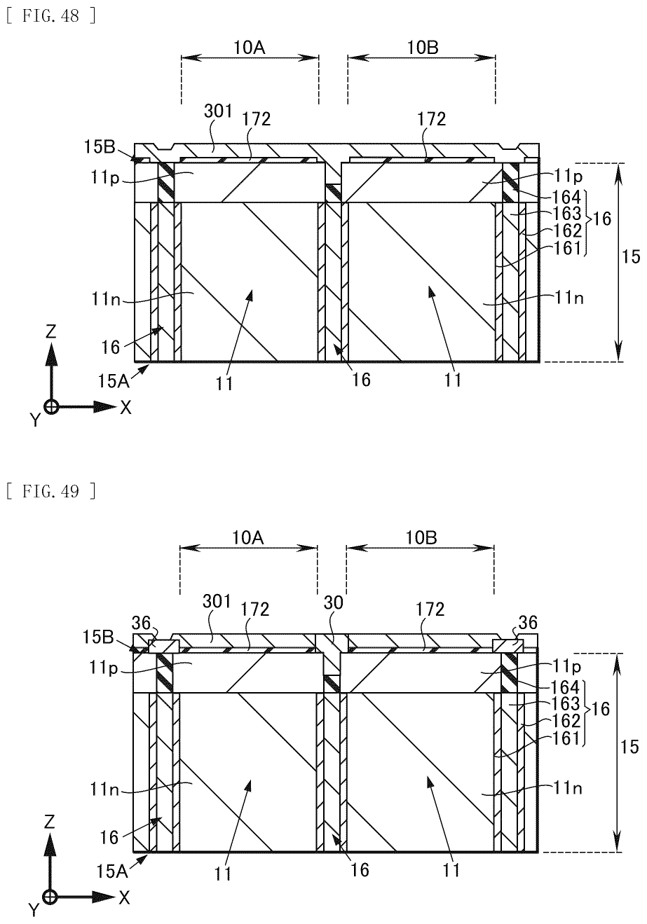

As with a step illustrated in FIG. 19 of the first manufacturing method, as illustrated in FIG. 48, the electrically conductive film 301 is formed on the entire surface of the base 15 including a top surface of the mask 172. The electrically conductive film 301 includes a material for forming the shared contact section 30. A portion of the electrically conductive film 301 is embedded in an upper portion of the groove 161 of the pixel separation region 16.

Subsequently, the electrically conductive film 301 is doped with an p-type impurity in a portion overlapping the pixel separation region 16 except for the formation region for the shared contact section 30 to form the p-type electrically conductive film 36.

As illustrated in FIG. 49, the electrically conductive film 301 is doped with an n-type impurity in the formation region for the shared contact section 30. When the electrically conductive film 301 is doped with the n-type impurity, the shared contact section 30 is substantially formed.

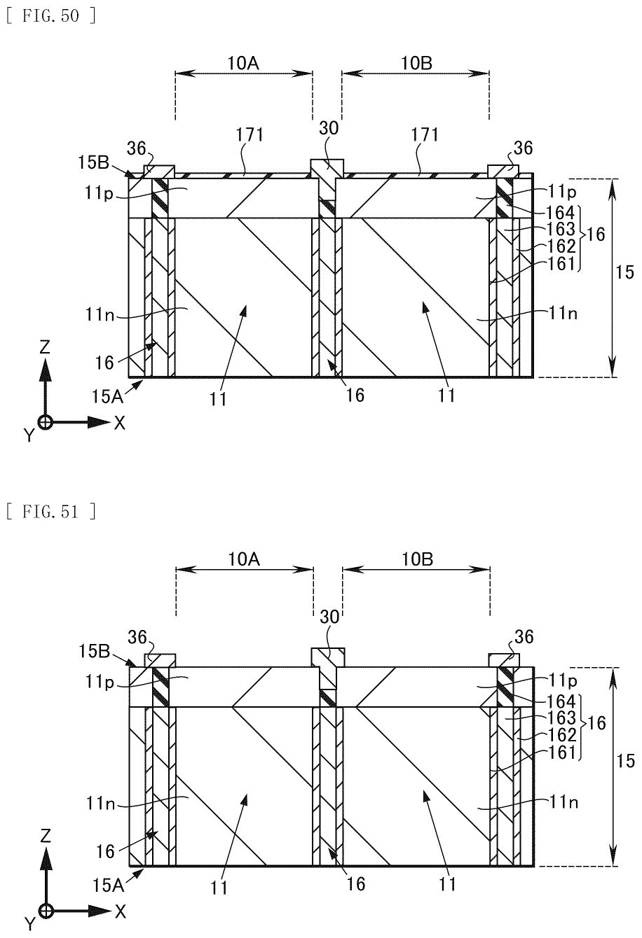

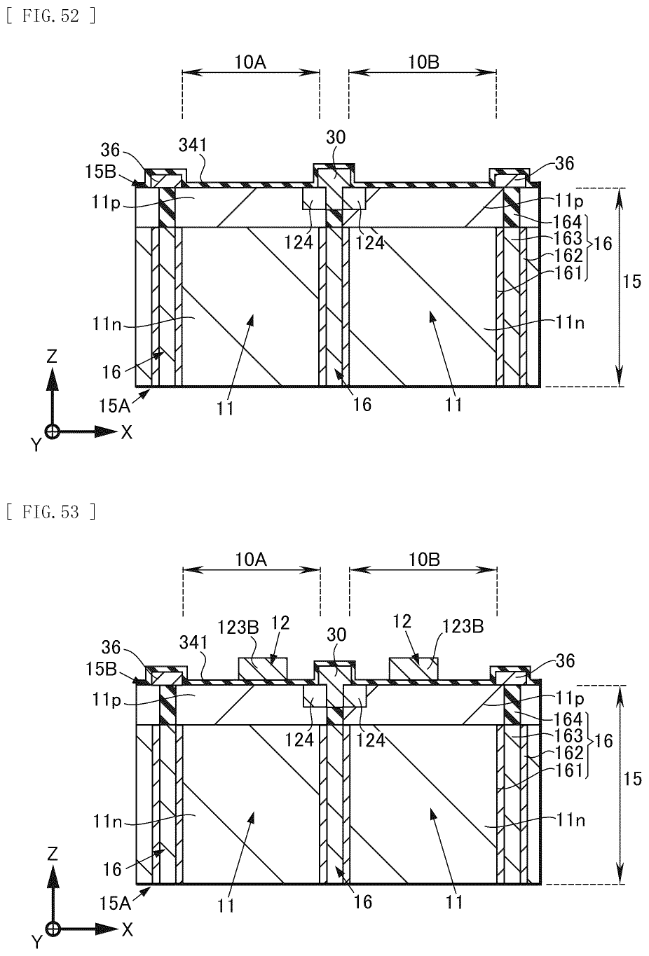

As with a step illustrated in FIG. 21 of the first manufacturing method, as illustrated in FIG. 50, the electrically conductive film 301 is subjected to patterning to remove the extra electrically conductive film 301, thereby forming the shared contact section 30 and the p-type electrically conductive film 36.

Subsequently, as illustrated in FIG. 51, the mask 172 is removed.

As illustrated in FIG. 52, the insulating film 341 is formed on the second surface 15B of the base 15 in the formation region for the pixel 10.

Subsequently, the n-type semiconductor region 124 of the transistor 12 is formed (refer to FIG. 53). The n-type semiconductor region 124 is formed by doping a surface portion of the second surface 15B of the base 15 with an n-type impurity through the insulating film 341. The side surface of the n-type semiconductor region 124 is in contact with the side surface of the shared contact section 30, and the side surface of the n-type semiconductor region 124 and the side surface of the shared contact section 30 are electrically coupled to each other.

As with a step illustrated in FIG. 12 of the first manufacturing method, as illustrated in FIG. 53, the gate electrode contact section 123B of the gate electrode 123 is formed on the insulating film 341.

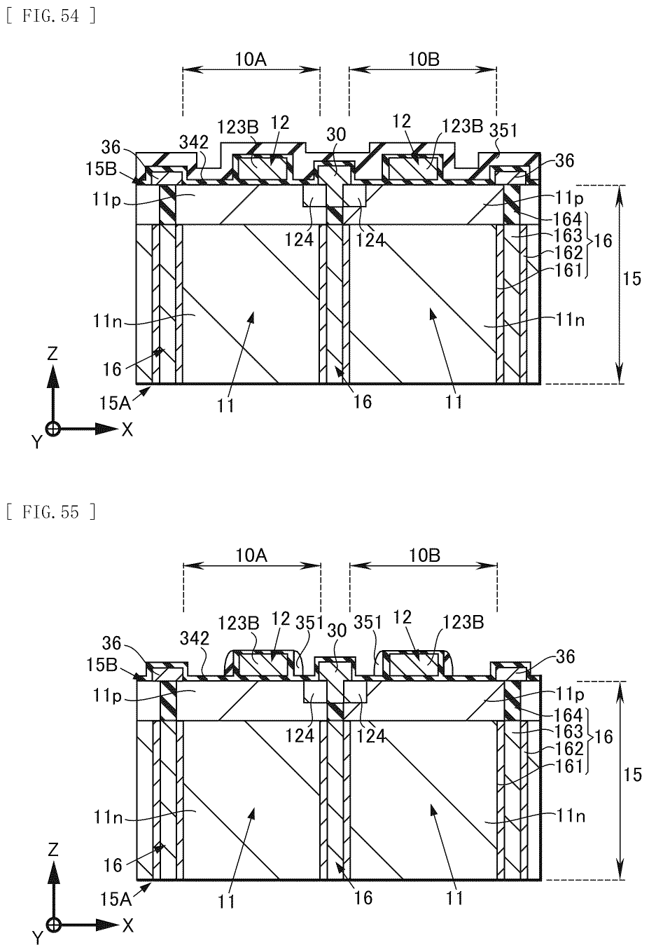

As with a step illustrated in FIG. 14 of the first manufacturing method, as illustrated in FIG. 54, the insulating film 342 and the insulating film 351 are formed in order on the entire surface of the base 15 on the side of the second surface 15B.

As with a step illustrated in FIG. 15 of the first manufacturing method, as illustrated in FIG. 55, the entire surface is subjected to etching, which causes the insulating film 351 on the side surface of the gate electrode contact section 123B to remain, and causes the insulating film 351 in another region to be removed. The remaining insulating film 351 is formed as a sidewall spacer.

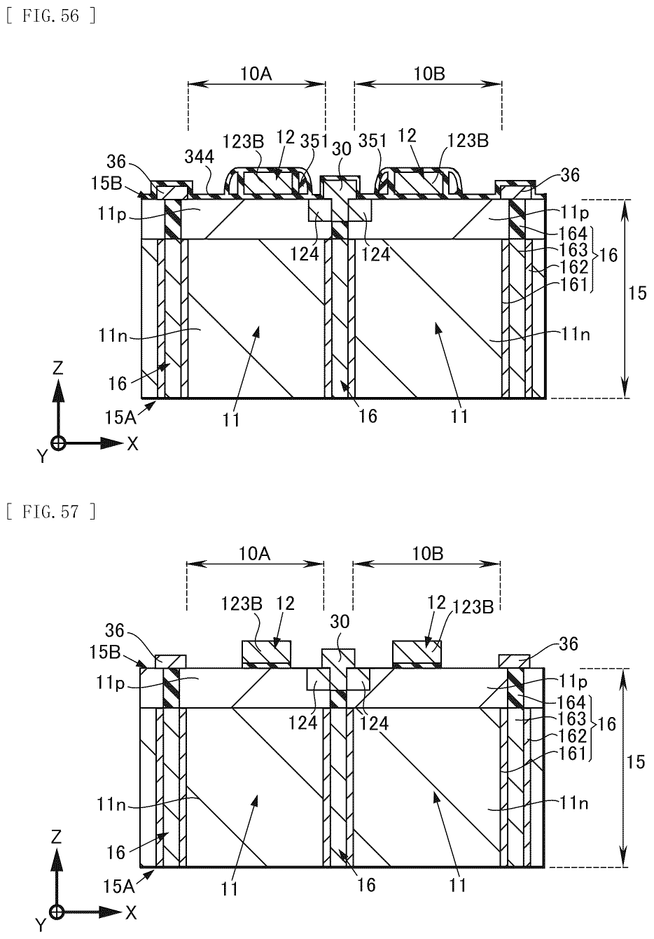

Subsequently, as illustrated in FIG. 56, an insulating film 344 that covers the gate electrode contact section 123B and the insulating film 351 is formed. The insulating film 344 is, for example, a SiO film.

As illustrated in FIG. 57, the insulating film 344, the insulating film 351, and the like are removed. Surfaces of the gate electrode contact section 123B, the shared contact section 30, and the like are exposed by this removal.

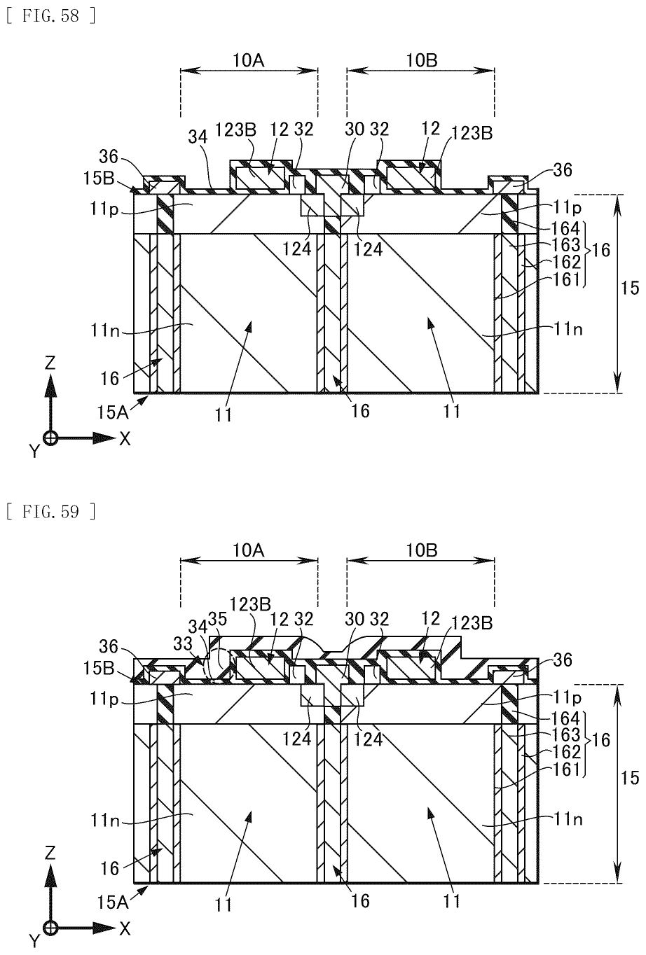

As illustrated in FIG. 58, the insulating film 34 that covers each of the gate electrode contact section 123B, the shared contact section 30, and the like is formed. The insulating film 34 is, for example, a SiO film as with the first manufacturing method.

Here, when the insulating film 34 is formed, a gap is formed between the gate electrode contact section 123B and the shared contact section 30. As a result, the low-dielectric constant region 32 is formed.

It is to be noted that when a thickness in the arrow-Z direction of the shared contact section 30 is set to be thick, a height in the same direction of the low-dielectric constant region 32 becomes high. That is, it is possible to increase a volume of the low-dielectric constant region 32, and it is possible to reduce the capacitance value of the parasitic capacitance.

Subsequently, as illustrated in FIG. 59, the insulating film 35 is formed on the insulating film 34.

Thereafter, a step illustrated in FIG. 25 and subsequent steps of the first manufacturing method are executed to thereby complete the solid-state imaging device 1 according to the sixth embodiment, and the manufacturing method ends.

Components other than the above-described components are the same or substantially the same as the components of the solid-state imaging device 1 according to the first embodiment or the second embodiment. In addition, the solid-state imaging device 1 according to the sixth embodiment may be applied to any of the solid-state imaging devices 1 according to the third to fifth embodiments.

### [Workings and Effects]

In the solid-state imaging device 1 according to the sixth embodiment illustrated in FIGS. 34 and 35, it is possible to obtain workings and effects similar to the workings and effects obtained by the solid-state imaging device 1 according to the first embodiment or the second embodiment.

In addition, in the manufacturing method of the solid-state imaging device 1 according to the sixth embodiment illustrated in FIGS. 36 to 59, it is possible to obtain workings and effects similar to the workings and effects obtained by the first manufacturing method.

### 7. Seventh Embodiment

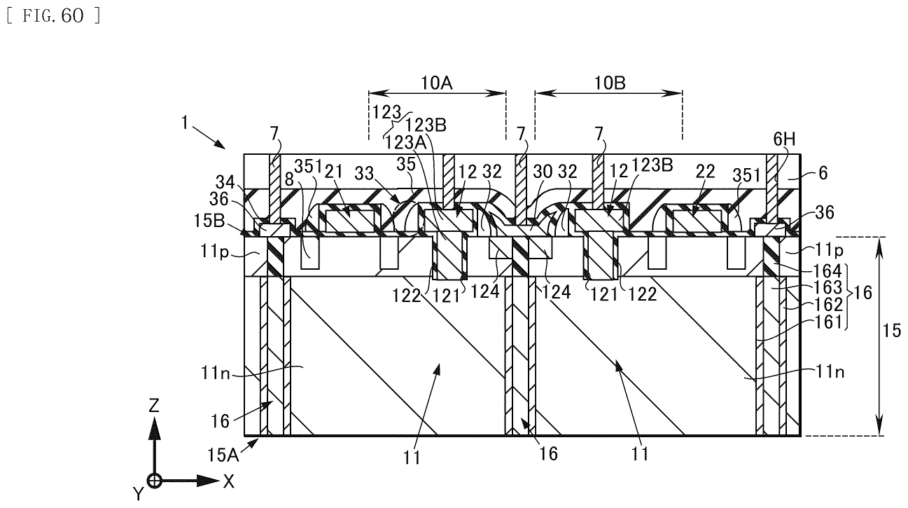

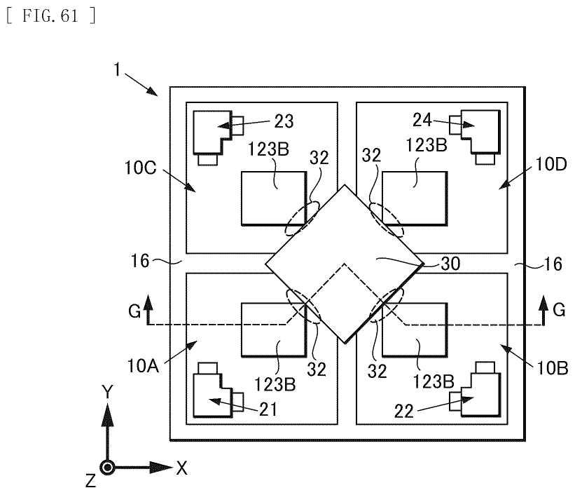

Description is given of the solid-state imaging device 1 according to the seventh embodiment of the present disclosure with reference to FIGS. 60 and 61.

### [Configuration of Solid-State Imaging Device 1]

FIG. 60 illustrates an example of a schematic longitudinal cross-sectional configuration of the pixel 10. FIG. 61 illustrates an example of a schematic planar configuration of the pixel 10.

As illustrated in FIGS. 60 and 61, in the solid-state imaging device 1 according to the seventh embodiment, a one-stage structure is adopted in which the pixel circuit 20 is constructed on the base 15. To describe this in detail, a transistor that constructs the pixel circuit 20 is provided on a portion of the second surface 15B of the base 15 at a position corresponding to the pixel 10.

Although an arrangement layout is not limited, in the seventh embodiment, the amplification transistor 21 is provided on the base 15 at a position corresponding to the pixel 10A that constructs the unit pixel. In addition, the selection transistor 22 is provided on the base 15 at a position corresponding to the pixel 10B. Likewise, the FD conversion gain switching transistor 23 is provided on the base 15 at a position corresponding to the pixel 10C, and the reset transistor 24 is provided on the base 15 at a position corresponding to the pixel 10D.

An element separation region 8 is provided around each of the amplification transistor 21, the selection transistor 22, the FD conversion gain switching transistor 23, and the reset transistor 24. Although a specific structure of the element separation region 8 is not described, the element separation region 8 is configured by a trench isolation structure having a groove and an embedded member embedded in the groove. The groove and the embedded member are not specifically denoted by reference numerals.

In addition, although a specific structure of each of the amplification transistor 21, the selection transistor 22, the FD conversion gain switching transistor 23, and the reset transistor 24 is not described, each of the amplification transistor 21, the selection transistor 22, the FD conversion gain switching transistor 23, and the reset transistor 24 includes a gate electrode and a pair of main electrodes. The gate electrode and the pair of main electrodes are not specifically denoted by reference numerals.

The gate electrode is formed in the same electrically conductive layer as, for example, the gate electrode contact section 123B of the transistor 12, and is formed by the same electrically conductive material as that of the gate electrode contact section 123B of the transistor 12. In addition, the pair of main electrodes is formed by the same n-type semiconductor region as the n-type semiconductor region 124 of the transistor 12.

Here, the insulating film 351 to be used as a sidewall spacer is provided on a side surface of the gate electrode of each of the amplification transistor 21, the selection transistor 22, the FD conversion gain switching transistor 23, and the reset transistor 24.

It is to be noted that the present technology is not limited to a case where one transistor that constructs the pixel circuit 20 is disposed at a position corresponding to one pixel 10. For example, one transistor may be disposed over two pixels 10. In addition, two transistors may be disposed at a position corresponding to one pixel 10.

Components other than the above-described components are the same or substantially the same as the components of the solid-state imaging device 1 according to the first embodiment or the second embodiment. In addition, the solid-state imaging device 1 according to the seventh embodiment may be applied to any of the solid-state imaging devices 1 according to the third to sixth embodiments.

### [Workings and Effects]

In the solid-state imaging device 1 according to the seventh embodiment illustrated in FIGS. 60 and 61, it is possible to obtain workings and effects similar to the workings and effects obtained by the solid-state imaging device 1 according to the first embodiment or the second embodiment.

### 8. Eighth Embodiment

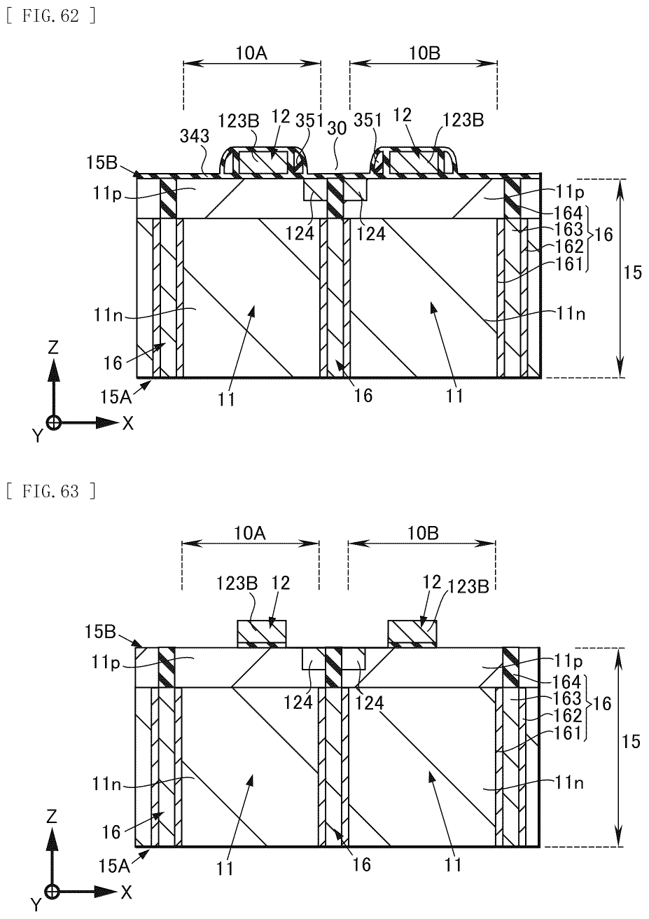

Description is given of the solid-state imaging device 1 according to the eighth embodiment of the present disclosure and a manufacturing method thereof with reference to FIGS. 62 to 65.

### [Manufacturing Method of Solid-State Imaging Device 1]

FIGS. 62 to 65 illustrate, step-by-step, an example of the manufacturing method of the solid-state imaging device 1 according to the eighth embodiment. It is to be noted that, in description of the manufacturing method, illustration and description of each of cross-sectional structures of the photoelectric conversion element 11 and the transistor (the transfer transistor) 12 are simplified or omitted.

As with a step illustrated in FIG. 17 of the first manufacturing method, the insulating film 351 to be used as a sidewall spacer is formed on the side surface of the gate electrode contact section 123B, and the insulating film 343 that covers the gate electrode contact section 123B and the insulating film 351 is formed (refer to FIG. 62).

As illustrated in FIG. 62 the n-type semiconductor region 124 as the other main electrode of the transistor 12 is formed.

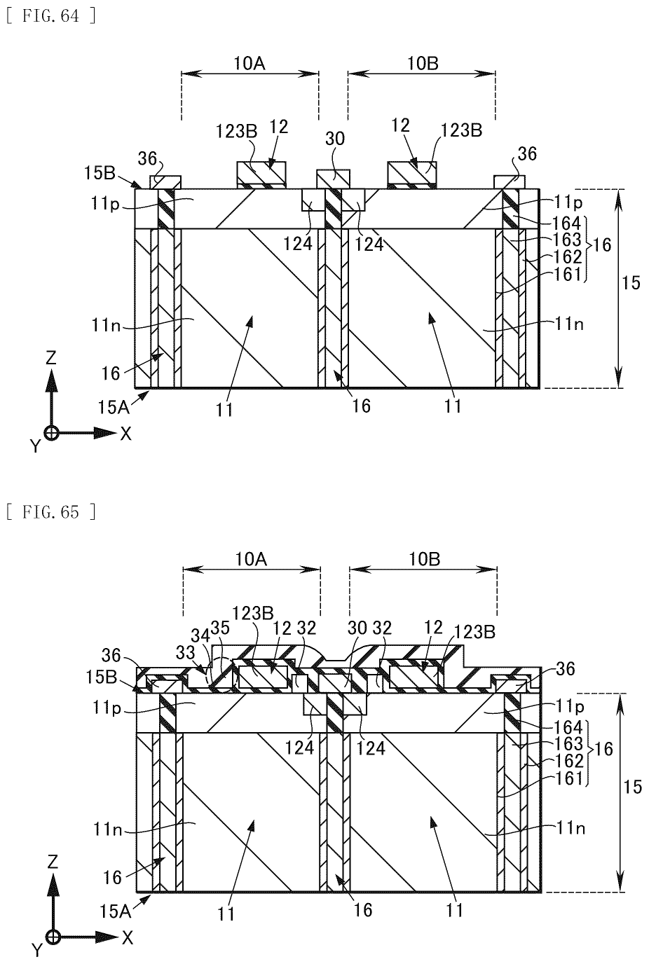

As illustrated in FIG. 63, the insulating film 343 and the insulating film 351 are selectively removed. That is, the sidewall spacer is removed.

Subsequently, as with the step illustrated in FIG. 22 of the first manufacturing method, as illustrated in FIG. 64, the shared contact section 30 and the p-type electrically conductive film 36 are formed.

Subsequently, as with a step illustrated in FIG. 23 of the first manufacturing method, the insulating film 34 that covers the gate electrode contact section 123B and the shared contact section 30 is formed (refer to FIG. 65). When the insulating film 34 is formed, the low-dielectric constant region 32 is formed between the gate electrode contact section 123B and the shared contact section 30.

As with a step illustrated in FIG. 24 of the first manufacturing method, as illustrated in FIG. 65, the insulating film 35 that covers the insulating film 34 is formed.

Thereafter, the step illustrated in FIG. 25 and subsequent steps of the first manufacturing method are executed to thereby complete the solid-state imaging device 1 according to the eighth embodiment, and the manufacturing method ends.

Components other than the above-described components are the same or substantially the same as the components of the solid-state imaging device 1 according to the first embodiment and the manufacturing method thereof.

### [Workings and Effects]

In the manufacturing method of the solid-state imaging device 1 according to the eighth embodiment illustrated in FIGS. 62 to 65, it is possible to obtain workings and effects similar to the workings and effects obtained by the manufacturing method of the solid-state imaging device 1 according to the first embodiment.

### 9. Ninth Embodiment

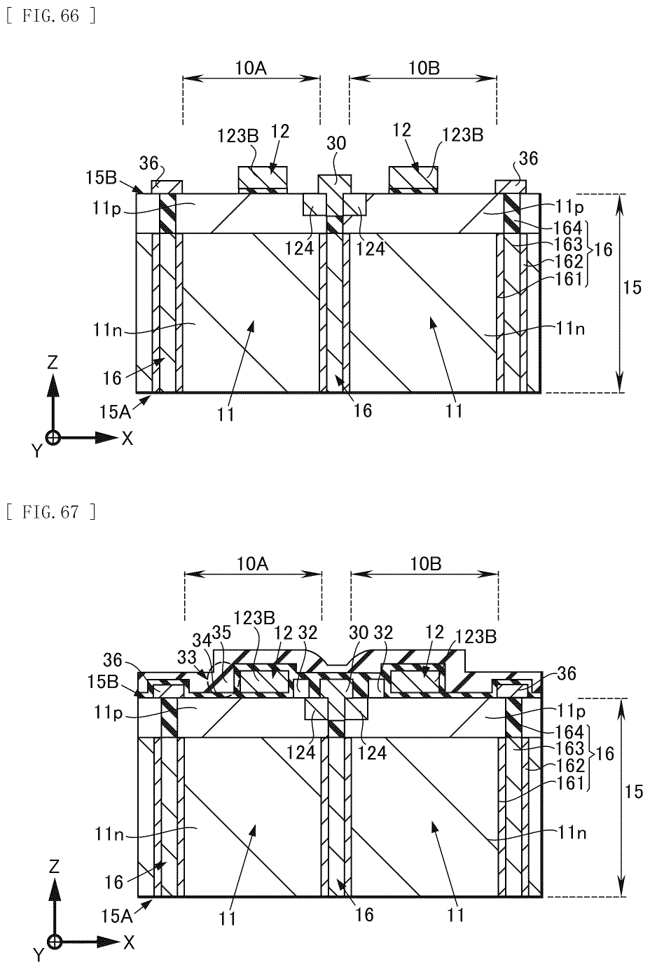

Description is given of the solid-state imaging device 1 according to the ninth embodiment of the present disclosure and a manufacturing method thereof with reference to FIGS. 66 and 67.

### [Manufacturing Method of Solid-State Imaging Device 1]

FIGS. 66 to 67 illustrate, step-by-step, an example of the manufacturing method of the solid-state imaging device 1 according to the ninth embodiment. It is to be noted that, in description of the manufacturing method, illustration and description of each of cross-sectional structures of the photoelectric conversion element 11 and the transistor (transfer transistor) 12 are simplified or omitted.

In the manufacturing method of the solid-state imaging device 1 according to the ninth embodiment, as with a step illustrated in FIG. 64 of the manufacturing method of the solid-state imaging device 1 according to the eighth embodiment (hereinafter simply referred to as an “eighth manufacturing method”), as illustrated in FIG. 66, the shared contact section 30 and the p-type electrically conductive film 36 are formed. Here, in the ninth embodiment, as with steps illustrated in FIGS. 47 to 53 of the manufacturing method of the solid-state imaging device 1 according to the sixth embodiment described above, a portion of the shared contact section 30 is embedded in the groove 161 of the pixel separation region 16.

As with a step illustrated in FIG. 65 of the eighth manufacturing method, as illustrated in FIG. 67, the insulating film 34 and the insulating film 35 are formed in order. Here, when the insulating film 34 is formed, the low-dielectric constant region 32 is formed between the gate electrode contact section 123B and the shared contact section 30.

Thereafter, the step illustrated in FIG. 25 and subsequent steps of the first manufacturing method are executed to thereby complete the solid-state imaging device 1 according to the ninth embodiment, and the manufacturing method ends.

Components other than the above-described components are the same or substantially the same as the components of the solid-state imaging device 1 according to the eighth embodiment and the manufacturing method thereof.

### [Workings and Effects]

In the manufacturing method of the solid-state imaging device 1 according to the ninth embodiment illustrated in FIGS. 66 and 67, it is possible to obtain a combination of workings and effects of the manufacturing method of the solid-state imaging device 1 according to the sixth embodiment and the manufacturing method of the solid-state imaging device 1 according to the eighth embodiment.

### 10. Tenth Embodiment

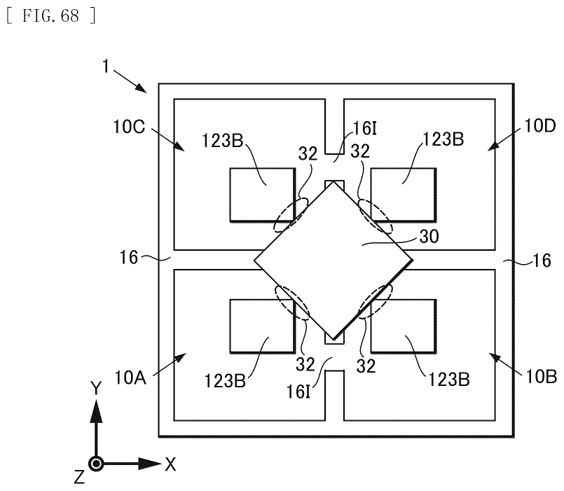

Description is given of the solid-state imaging device 1 according to the tenth embodiment of the present disclosure with reference to FIG. 68.

### [Configuration of Solid-State Imaging Device 1]

FIG. 68 illustrates an example of a schematic planar configuration of the pixel 10.

As illustrated in FIG. 68, in the solid-state imaging device 1 according to the tenth embodiment, the pixel separation region 16 is provided in a portion of a region around the pixel 10.

In the tenth embodiment, a separation section 16I where the pixel separation region 16 has a break is provided between the pixel 10A and the pixel 10B that construct the unit pixel. In addition, the separation section 16I where the pixel separation region 16 has a break is provided between the pixel 10C and the pixel 10D.

Components other than the above-described components are the same or substantially the same as the components of any of the solid-state imaging devices 1 according to the first to ninth embodiments.

### [Workings and Effects]

In the solid-state imaging device 1 according to the tenth embodiment illustrated in FIG. 68, it is possible to obtain workings and effects similar to the workings and effects obtained by any of the solid-state imaging devices 1 according to the first to ninth embodiments.

### 11. Eleventh Embodiment

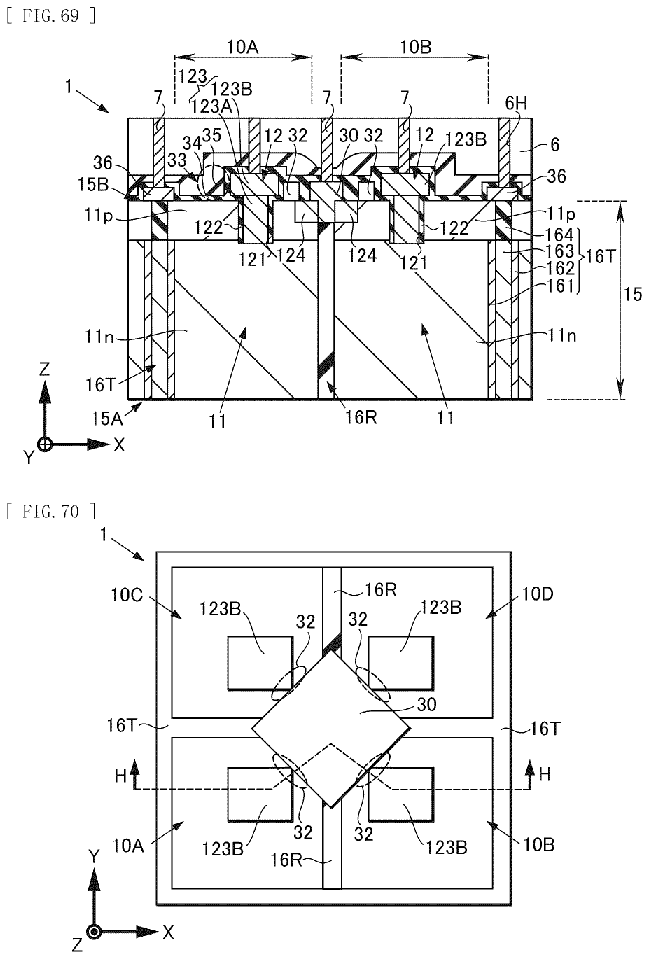

Description is given of the solid-state imaging device 1 according to the eleventh embodiment of the present disclosure with reference to FIGS. 69 and 70.

### [Configuration of Solid-State Imaging Device 1]

FIG. 69 illustrates an example of a schematic longitudinal cross-sectional configuration of the pixel 10. FIG. 70 illustrates an example of a schematic planar configuration of the pixel 10.

As illustrated in FIGS. 69 and 70, in the solid-state imaging device 1 according to the eleventh embodiment, the pixel separation region 16 includes two pixel separation regions 16T and 16R.

The pixel separation region 16T is the same component as the pixel separation region 16 of the solid-state imaging device 1 according to the first embodiment or the second embodiment. The reference numeral is changed for distinction. The pixel separation region 16T has the groove 161, the embedded member 163, and the embedded member 164. The pixel separation region 16T is provided around the unit pixel, between the pixel 10A and the pixel 10C, and between the pixel 10B and the pixel 10D.

The pixel separation region 16R is the same component as the pixel separation region 16 of the solid-state imaging device 1 according to the third embodiment. Likewise, the reference numeral is changed for distinction. The pixel separation region 16R includes an insulator region. The pixel separation region 16R is provided between the pixel 10A and the pixel 10B and between the pixel 10C and the pixel 10D.

Components other than the above-described components are the same or substantially the same as the components of any of the solid-state imaging devices 1 according to the first to tenth embodiments.

### [Workings and Effects]

In the solid-state imaging device 1 according to the eleventh embodiment illustrated in FIGS. 69 and 70, it is possible to obtain workings and effects similar to the workings and effects obtained by any of the solid-state imaging devices 1 according to the first to tenth embodiments.

### 12. Twelfth Embodiment

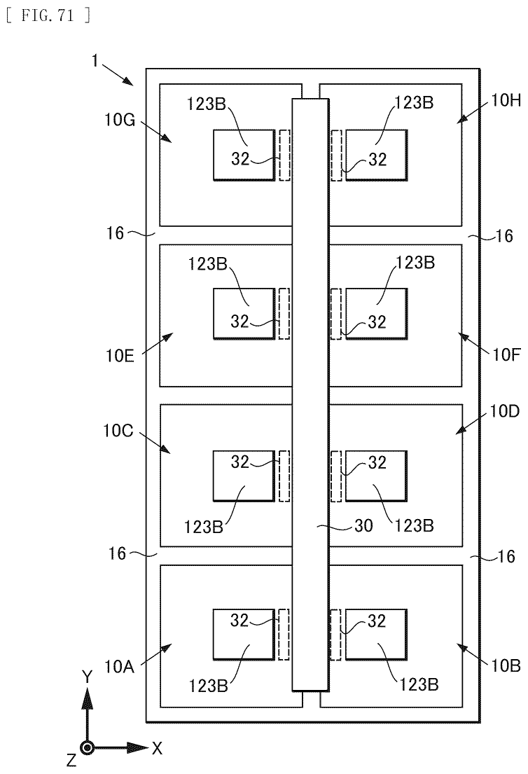

Description is given of the solid-state imaging device 1 according to the twelfth embodiment of the present disclosure with reference to FIG. 71.

### [Configuration of Solid-State Imaging Device 1]

FIG. 71 illustrates an example of a schematic planar configuration of the pixel 10.

As illustrated in FIG. 71, in the solid-state imaging device 1 according to the twelfth embodiment, the unit pixel is constructed by a total of eight pixels 10A to 10H. The pixel 10B is arranged adjacent to the pixel 10A in the arrow-X direction. The pixel 10C is arranged adjacent to the pixel 10A in the arrow-Y direction. The pixel 10D is arranged adjacent to the pixel 10C in the arrow-X direction. The pixel 10E is arranged adjacent to the pixel 10C in the arrow-Y direction. The pixel 10F is arranged adjacent to the pixel 10E in the arrow-X direction. The pixel 10G is arranged adjacent to the pixel 10F in the arrow-Y direction. The pixel 10H is arranged adjacent to the pixel 10G in the arrow-X direction.

The shared contact section 30 is provided to extend between the pixel 10A and the pixel 10B, between the pixel 10C and the pixel 10D, between the pixel 10E and the pixel 10F, and between the pixel 10G and the pixel 10H. Furthermore, the shared contact section 30 is shared by all the pixels 10A to 10H in the unit pixel.

Furthermore, in the twelfth embodiment, one pixel circuit 20 (refer to FIG. 1) is provided for one unit pixel.

Components other than the above-described components are the same or substantially the same as the components of any of the solid-state imaging devices 1 according to the first to eleventh embodiments.

### [Workings and Effects]

In the solid-state imaging device 1 according to the twelfth embodiment illustrated in FIG. 71, it is possible to obtain workings and effects similar to the workings and effects obtained by any of the solid-state imaging devices 1 according to the first to eleventh embodiments.

### 13. Example of Application to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

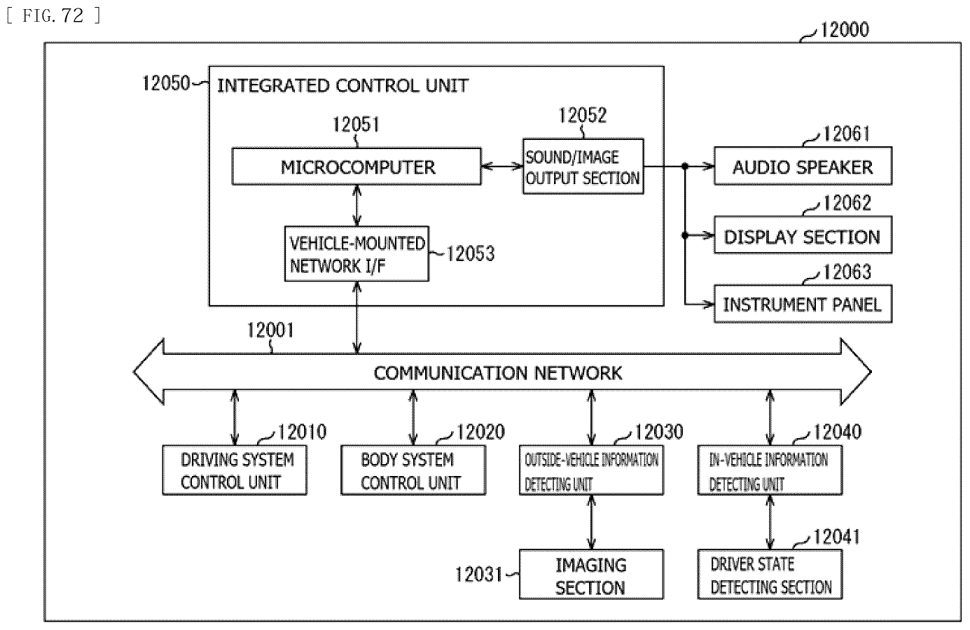

FIG. 72 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 72, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 72, an audio speaker 12061, a display section 12062, and an instrument panel 12063 are illustrated as the output device. The display section 12062 may, for example, include at least one of an on-board display and a head-up display.

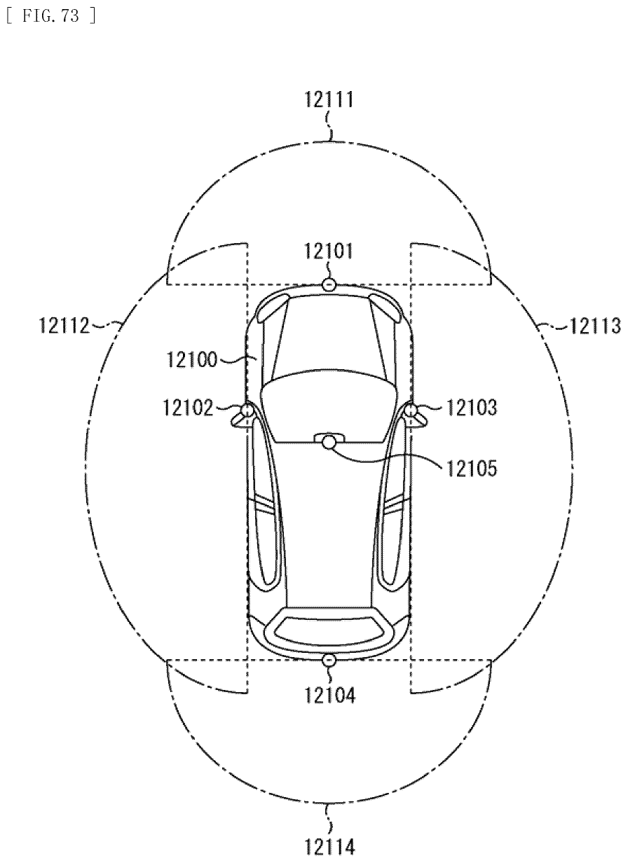

FIG. 73 is a diagram depicting an example of the installation position of the imaging section 12031.

In FIG. 73, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 73 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to the present disclosure may be applied. The technology according to the present disclosure may be applied to the imaging section 12031 among the configurations described above. The application of the technology according to the present disclosure to the imaging section 12031 enables achievement of the imaging section 12031 of a simpler configuration.

### 14. Other Embodiments

The present technology is not limited to the embodiments described above, and various modifications may be made without departing from the gist of the present technology.

For example, the solid-state imaging devices according to two or more embodiments, among the solid-state imaging devices according to the foregoing first to twelfth embodiments, may be combined.

Furthermore, it is possible to widely apply the present technology to a light receiving device, a photoelectric conversion device, a photodetection device, and the like to be used for sensing applications, in addition to imaging applications. Moreover, the solid-state imaging device may use incident light of infrared light, ultraviolet light, or electromagnetic waves, for example, in addition to incident light of visible light. Furthermore, the present technology may have a configuration in which any desired color filter or band pass filter is provided above the photoelectric conversion element on the light incident side, and desired incident light is received.

A solid-state imaging device according to a first aspect of the present disclosure includes a low-dielectric constant region between a first gate electrode of a first transistor and a floating diffusion. This makes it possible to reduce a capacitance value of a parasitic capacitance in which the first gate electrode serves as one electrode, the low-dielectric constant region serves as a dielectric, and the floating diffusion serves as another electrode. That is, the capacitance value of the parasitic capacitance added to the floating diffusion is reduced, which makes it possible to reduce variations in the capacitance value. Accordingly, in the solid-state imaging device, it is possible to suppress signal variations and signal delay due to the parasitic capacitance.

A solid-state imaging device according to a second aspect of the present disclosure includes the low-dielectric constant region between a second gate electrode of a second transistor and the floating diffusion, in the solid-state imaging device according to the first aspect. This makes it possible to reduce a capacitance value of a parasitic capacitance in which the second gate electrode serves as one electrode, the low-dielectric constant region serves as a dielectric, and the floating diffusion serves as another electrode. That is, the capacitance value of the parasitic capacitance added to the floating diffusion is reduced, which makes it possible to reduce variations in the capacitance value. Accordingly, in the solid-state imaging device, it is possible to suppress signal variations and signal delay due to the parasitic capacitance.

In a solid-state imaging device according to a third aspect of the present disclosure, the low-dielectric constant region is a gap, in solid-state imaging device according to the first aspect or the second aspect. This allows the low-dielectric constant region 32 to have a simple configuration, which makes it possible to easily reduce the capacitance value of the parasitic capacitance.

In a solid-state imaging device according to a fourth aspect of the present disclosure, the low-dielectric constant region is formed by a low-dielectric constant material, in the solid-state imaging device according to the first aspect or the second aspect. This allows the low-dielectric constant region 32 to have a simple configuration, which makes it possible to easily reduce the capacitance value of the parasitic capacitance.

### <Configuration of Present Technology>

The present technology has the following configurations. According to the present technology having the following configurations, it is possible, in a solid-state imaging device, to suppress signal variations and signal delay due to a parasitic capacitance.

(1)

A solid-state imaging device including:
a first pixel that is provided on a side of a first surface of a base, and includes a first photoelectric conversion element that converts light into electric charge, the side of the first surface being a light incident side;
a first transistor that is provided on a side of a second surface opposite to the first surface of the base at a position corresponding to the first pixel, and includes a first gate electrode and a pair of main electrodes, one of the pair of main electrodes being electrically coupled to the first photoelectric conversion element;
a floating diffusion that is provided on the side of the second surface of the base, and is electrically coupled to another main electrode of the first transistor; and
a low-dielectric constant region that is provided between the floating diffusion and the first gate electrode opposed to the floating diffusion, and has a lower dielectric constant than a dielectric constant of a non-opposed region.
   (2)

The solid-state imaging device according to (1), further including:
a second pixel that is provided adjacent to the first pixel on the side of the first surface of the base, and includes a second photoelectric conversion element that converts light into electric charge;
a second transistor that is provided on the side of the second surface of the base at a position corresponding to the second pixel, and includes a second gate electrode and a pair of main electrodes, one of the pair of main electrodes being electrically coupled to the second photoelectric conversion element, and another main electrode being electrically coupled to the floating diffusion; and
the low-dielectric constant region that is provided between the floating diffusion and the second gate electrode opposed to the floating diffusion.
   (3)

The solid-state imaging device according to (2), further including:
a pixel separation region that is provided in the base between the first pixel and the second pixel, and electrically and optically separates the first pixel and the second pixel from each other; and
a shared contact section that is provided to overlap the pixel separation region on the side of the second surface of the base, electrically couples the other main electrode of the first transistor and the other main electrode of the second transistor to each other, and is electrically coupled to the floating diffusion, in which
the low-dielectric constant region is provided between the first gate electrode and the shared contact section and between the second gate electrode and the shared contact section.
   (4)

The solid-state imaging device according to (3), in which
a side surface on a side of the first gate electrode of the shared contact section is formed in a shape that approaches the first gate electrode as moving away from the second surface of the base, and
a side surface on a side of the second gate electrode of the shared contact section is formed in a shape that approaches the second gate electrode as moving away from the second surface of the base.
   (5)

The solid-state imaging device according to (3) or (4), in which
the pixel separation region has
a groove formed in a depth direction of the base, and
an embedded member embedded in the groove.
   (6)

The solid-state imaging device according to (3) or (4), in which the pixel separation region includes an insulator region formed in a depth direction of the base.
(7)

The solid-state imaging device according to (3), in which a portion of the shared contact section is embedded in the base.

(8)

The solid-state imaging device according to any one of (1) to (7), in which the low-dielectric constant region includes a gap.

(9)

The solid-state imaging device according to (8), in which there is a vacuum in the gap, or the gap is filled with air or an inert gas.

(10)

The solid-state imaging device according to any one of (1) to (7), in which the low-dielectric constant region is formed by a low-dielectric constant material.

(11)

The solid-state imaging device according to (10), in which the low-dielectric constant material includes silicon oxide or carbon-doped silicon oxide.

(12)

The solid-state imaging device according to (2), in which a sidewall spacer is provided on a side surface of the non-opposed region of the first gate electrode and a side surface of the non-opposed region of the second gate electrode.

(13)

The solid-state imaging device according to (12), in which the low-dielectric constant region has a lower dielectric constant than a dielectric constant of the sidewall spacer.

(14)

The solid-state imaging device according to (2), further including a transistor of a pixel circuit on the side of the second surface corresponding to each of the first pixel and the second pixel of the base, the pixel circuit that processes the electric charge generated by the first photoelectric conversion element or the second photoelectric conversion element, in which
a sidewall spacer is provided on a side wall of a gate electrode of the transistor.

The present application claims the benefit of Japanese Priority Patent Application JP2022-160068 filed with the Japan Patent Office on Oct. 4, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging device comprising:
a first pixel that is provided on a side of a first surface of a base, and includes a first photoelectric conversion element that converts light into electric charge, the side of the first surface being a light incident side;
a first transistor that is provided on a side of a second surface opposite to the first surface of the base at a position corresponding to the first pixel, and includes a first gate electrode and a pair of main electrodes, one of the pair of main electrodes being electrically coupled to the first photoelectric conversion element;
a floating diffusion that is provided on the side of the second surface of the base, and is electrically coupled to another main electrode of the first transistor; and
a low-dielectric constant region that is provided between the floating diffusion and the first gate electrode opposed to the floating diffusion, and has a lower dielectric constant than a dielectric constant of a non-opposed region.

2. The solid-state imaging device according to claim 1, further comprising:
a second pixel that is provided adjacent to the first pixel on the side of the first surface of the base, and includes a second photoelectric conversion element that converts light into electric charge;
a second transistor that is provided on the side of the second surface of the base at a position corresponding to the second pixel, and includes a second gate electrode and a pair of main electrodes, one of the pair of main electrodes being electrically coupled to the second photoelectric conversion element, and another main electrode being electrically coupled to the floating diffusion; and
the low-dielectric constant region that is provided between the floating diffusion and the second gate electrode opposed to the floating diffusion.

3. The solid-state imaging device according to claim 2, further comprising:
a pixel separation region that is provided in the base between the first pixel and the second pixel, and electrically and optically separates the first pixel and the second pixel from each other; and
a shared contact section that is provided to overlap the pixel separation region on the side of the second surface of the base, electrically couples the other main electrode of the first transistor and the other main electrode of the second transistor to each other, and is electrically coupled to the floating diffusion, wherein
the low-dielectric constant region is provided between the first gate electrode and the shared contact section and between the second gate electrode and the shared contact section.

4. The solid-state imaging device according to claim 3, wherein
a side surface on a side of the first gate electrode of the shared contact section is formed in a shape that approaches the first gate electrode as moving away from the second surface of the base, and
a side surface on a side of the second gate electrode of the shared contact section is formed in a shape that approaches the second gate electrode as moving away from the second surface of the base.

5. The solid-state imaging device according to claim 3, wherein
the pixel separation region has
a groove formed in a depth direction of the base, and
an embedded member embedded in the groove.

6. The solid-state imaging device according to claim 3, wherein the pixel separation region includes an insulator region formed in a depth direction of the base.

7. The solid-state imaging device according to claim 3, wherein a portion of the shared contact section is embedded in the base.

8. The solid-state imaging device according to claim 1, wherein the low-dielectric constant region comprises a gap.

9. The solid-state imaging device according to claim 8, wherein there is a vacuum in the gap, or the gap is filled with air or an inert gas.

10. The solid-state imaging device according to claim 1, wherein the low-dielectric constant region is formed by a low-dielectric constant material.

11. The solid-state imaging device according to claim 10, wherein the low-dielectric constant material comprises silicon oxide or carbon-doped silicon oxide.

12. The solid-state imaging device according to claim 2, wherein a sidewall spacer is provided on a side surface of the non-opposed region of the first gate electrode and a side surface of the non-opposed region of the second gate electrode.

13. The solid-state imaging device according to claim 12, wherein the low-dielectric constant region has a lower dielectric constant than a dielectric constant of the sidewall spacer.

14. The solid-state imaging device according to claim 2, further comprising a transistor of a pixel circuit on the side of the second surface corresponding to each of the first pixel and the second pixel of the base, the pixel circuit that processes the electric charge generated by the first photoelectric conversion element or the second photoelectric conversion element, wherein
a sidewall spacer is provided on a side wall of a gate electrode of the transistor.
